(19) United States
(12) Patent Application Publication
(10) Pub. No.: US 2025/0216582 A1
(43) Pub. Date: Jul. 3, 2025

(54) PHASE MODULATING THIN FILM FOR LONG-WAVE INFRARED THERMAL IMAGING

(71) Applicant: Samsung Electronics Co., Ltd., Suwon-si (KR)

(72) Inventors: Haeri Park HANANIA, Sierra Madre, CA (US); Radwanul Hasan SIDDIQUE, Monrovia, CA (US); Shailabh KUMAR, Pasadena, CA (US)

(21) Appl. No.: 18/651,684

(22) Filed: Apr. 30, 2024

Related U.S. Application Data
(60) Provisional application No. 63/615,782, filed on Dec. 28, 2023.

(51) Int. Cl. G02B 1/00; B82Y 20/00; B82Y 40/00; G01J 5/00

(52) U.S. Cl. CPC G02B 1/002; B82Y 20/00; B82Y 40/00; G01J 2005/0077

(57) ABSTRACT

Provided are systems, methods, and apparatuses for phase modulating thin film for long-wave infrared thermal imaging. In one or more examples, the systems, devices, and methods include forming a first thin film layer of a first metalens of the metalens array and forming a nanostructure in the first thin film layer. In some examples, the systems, devices, and methods include forming at least one thin film layer of a second metalens of the metalens array, integrating the first metalens on a first pixel of a pixel array of the thermal camera, the first metalens being positioned over at least a portion of the first pixel, and integrating the second metalens on a second pixel of the pixel array, the second metalens being positioned over at least a portion of the second pixel.

### CROSS-REFERENCE TO RELATED APPLICATIONS

This application claims the benefit of U.S. Provisional Patent Application Ser. No. 63/615,782 Dec. 28, 2023, which is incorporated by reference herein for all purposes.

### TECHNICAL FIELD

The disclosure relates generally to thermal imaging, and more particularly to phase modulating thin film for long-wave infrared thermal imaging.

### BACKGROUND

The present background section is intended to provide context only, and the disclosure of any concept in this section does not constitute an admission that said concept is prior art.

Thermal imaging is a technology that converts thermal energy (heat) into visible light. Thermal imaging uses a sensor to convert infrared (IR) radiation into a visible image. However, components for thermal imaging are bulky and expensive. A need remains for systems and methods that decreasing the size of componentry in thermal imaging while increasing efficient power usage.

The above information disclosed in this Background section is only for enhancement of understanding of the background of the disclosure and therefore it may contain information that does not constitute prior art.

### SUMMARY

In various embodiments, described herein include systems, methods, and apparatuses for phase modulating thin film for long-wave infrared thermal imaging. In some aspects, the techniques described herein relate to a method of forming a metalens array of a thermal camera, the method including: forming a first thin film layer of a first metalens of the metalens array; forming a nanostructure in the first thin film layer, the nanostructure including at least one of a hole through the first thin film layer, a pillar extending from a bottom surface of the first thin film layer, or diffraction grating on at least one of a top surface or the bottom surface of the first thin film layer; forming at least one thin film layer of a second metalens of the metalens array; integrating the first metalens on a first pixel of a pixel array of the thermal camera, the first metalens being positioned over at least a portion of the first pixel; and integrating the second metalens on a second pixel of the pixel array, the second metalens being positioned over at least a portion of the second pixel.

In some aspects, the techniques described herein relate to a method, further including forming a second thin film layer of the first metalens, wherein at least one of the first thin film layer or the second thin film layer is formed with at least one low refractive index material, at least one high refractive index material, or a combination of the at least one low refractive index material and the at least one high refractive index material.

In some aspects, the techniques described herein relate to a method, further including forming an antireflective surface on a surface of the first metalens, the antireflective surface including at least one of photoresist, an electron-beam resist, a dielectric material, germanium, or zinc selenide.

In some aspects, the techniques described herein relate to a method, wherein the nanostructure is configured to route thermal radiation incident upon the first metalens to a thermal sensor membrane of the first pixel, the first pixel being a first thermal sensor pixel, the pixel array including a thermal sensor array of the thermal camera.

In some aspects, the techniques described herein relate to a method, wherein the nanostructure is configured to modulate a phase of thermal radiation incident on the first metalens.

In some aspects, the techniques described herein relate to a method, wherein the nanostructure is configured to allow thermal radiation with wavelengths between 8 and 15 micrometers to pass through the first metalens.

In some aspects, the techniques described herein relate to a method, wherein the first metalens includes at least one embedded liquid crystal layer.

In some aspects, the techniques described herein relate to a method, wherein the nanostructure of the first metalens provides up to a 2Pi phase shift of thermal radiation incident upon the first metalens.

In some aspects, the techniques described herein relate to a method, wherein, based on the nanostructure, a phase modulation of the first metalens varies from a phase modulation of the second metalens.

In some aspects, the techniques described herein relate to a method, wherein: the metalens array is configured as a global lens of the thermal camera, and based at least on the nanostructure, a phase profile of each metalens of the metalens array is configured to vary spatially across the pixel array.

In some aspects, the techniques described herein relate to a method, wherein a diameter of the hole or the pillar ranges between 100 micrometers and 1 nanometer.

In some aspects, the techniques described herein relate to a thermal camera, including: a first thin film layer of a first metalens of a metalens array of the thermal camera; a nanostructure formed in the first thin film layer, the nanostructure including at least one of a hole through the first thin film layer, a pillar extending from a bottom surface of the first thin film layer, or diffraction grating on at least one of a top surface or the bottom surface of the first thin film layer; and at least one thin film layer of a second metalens of the metalens array, wherein: the first metalens is integrated on a first pixel of a pixel array of the thermal camera, the first metalens being positioned over at least a portion of the first pixel; and the second metalens is integrated on a second pixel of the pixel array, the second metalens being positioned over at least a portion of the second pixel.

In some aspects, the techniques described herein relate to a thermal camera, wherein: the first metalens further includes a second thin film layer, and at least one of the first thin film layer or the second thin film layer is formed with at least one low refractive index material, at least one high refractive index material, or a combination of the at least one low refractive index material and the at least one high refractive index material.

In some aspects, the techniques described herein relate to a thermal camera, wherein the thermal camera further includes an antireflective surface formed on a surface of the first metalens, the antireflective surface including at least one of a photoresist, an electron-beam resist, a dielectric material, germanium, or zinc selenide.

In some aspects, the techniques described herein relate to a thermal camera, wherein the nanostructure is configured to route thermal radiation incident upon the first metalens to a thermal sensor membrane of the first pixel, the first pixel being a first thermal sensor pixel, the pixel array including a thermal sensor array of the thermal camera.

In some aspects, the techniques described herein relate to a thermal camera, wherein the nanostructure is configured to modulate a phase of thermal radiation incident on the first metalens.

In some aspects, the techniques described herein relate to a thermal camera, wherein the nanostructure is configured to allow thermal radiation with wavelengths between 8 and 15 micrometers to pass through the first metalens.

In some aspects, the techniques described herein relate to a thermal camera system including: a metalens array configured to guide thermal radiation, the metalens array including: a first thin film layer of a first metalens; at least one thin film layer of a second metalens; and a nanostructure formed in the first thin film layer, the nanostructure including at least one of a hole through the first thin film layer, a pillar extending from a bottom surface of the first thin film layer, or diffraction grating on at least one of a top surface or the bottom surface of the first thin film layer; a thermal sensor array configured to detect the thermal radiation via the metalens array, wherein: the first metalens is integrated on a first pixel of the thermal sensor array, the first metalens being positioned over at least a portion of the first pixel, and the second metalens is integrated on a second pixel of the thermal sensor array, the second metalens being positioned over at least a portion of the second pixel; an image processor to process signals of the thermal radiation generated by the thermal sensor array; and a thermal display configured to indicate a relative temperature of an object based on an output of the image processor.

In some aspects, the techniques described herein relate to a thermal camera system, wherein: the first metalens further includes a second thin film layer, and at least one of the first thin film layer or the second thin film layer is formed with at least one low refractive index material, at least one high refractive index material, or a combination of the at least one low refractive index material and the at least one high refractive index material.

In some aspects, the techniques described herein relate to a thermal camera system, wherein the thermal camera system further includes an antireflective surface formed on a surface of the first metalens, the antireflective surface including at least one of a photoresist, an electron-beam resist, a dielectric material, germanium, or zinc selenide.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

The techniques described herein include multiple advantages and benefits. Unlike bulky and expensive components of some thermal cameras, the present techniques significantly reduce the size and expense of thermal imaging components. For example, phase modulating thin films for long wave infrared (LWIR) are in the range of around 10 μm, which makes phase modulating thin film lenses up to 1000× thinner and significantly lighter than other thermal lenses. Also, phase modulating thin films designed for LWIR range allow phase modulation of thermal wavelengths (focusing, steering, scattering, etc.). Also, phase modulating thin film lenses for thermal imaging provide up to a 2Pi radian phase shift. Accordingly, phase modulating thin film lenses for thermal imaging may be optimized for a variety of chief ray angles (CRAs).

### BRIEF DESCRIPTION OF THE DRAWINGS

The above-mentioned aspects and other aspects of the present techniques will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings wherein:

FIG. 1 illustrates an example system in accordance with one or more implementations as described herein.

FIG. 2 illustrates details of the system of FIG. 1, according to one or more implementations as described herein.

FIG. 3A and FIG. 3B illustrate example systems in accordance with one or more implementations as described herein.

FIG. 4A and FIG. 4B illustrate example systems in accordance with one or more implementations as described herein.

FIG. 5 illustrates an example system in accordance with one or more implementations as described herein.

FIG. 6A and FIG. 6B illustrate example systems in accordance with one or more implementations as described herein.

FIG. 7A and FIG. 7B illustrate example systems in accordance with one or more implementations as described herein.

FIG. 8 illustrates an example system in accordance with one or more implementations as described herein.

FIG. 9 illustrates an example system in accordance with one or more implementations as described herein.

FIG. 10 depicts a flow diagram illustrating an example method associated with the disclosed systems, in accordance with example implementations described herein.

FIG. 11 depicts a flow diagram illustrating an example method associated with the disclosed systems, in accordance with example implementations described herein.

FIG. 12 depicts a flow diagram illustrating an example method associated with the disclosed systems, in accordance with example implementations described herein.

While the present techniques are susceptible to various modifications and alternative forms, specific embodiments thereof are shown by way of example in the drawings and will herein be described. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of an entirely hardware embodiment, an entirely computer program product embodiment, and/or an embodiment that comprises combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments can produce specifically-configured machines performing the steps or operations specified in the block diagrams and flowchart illustrations. Accordingly, the block diagrams and flowchart illustrations support various combinations of embodiments for performing the specified instructions, operations, or steps.

The following description is presented to enable one of ordinary skill in the art to make and use the subject matter disclosed herein and to incorporate it in the context of particular applications. While the following is directed to specific examples, other and further examples may be devised without departing from the basic scope thereof.

Various modifications, as well as a variety of uses in different applications, will be readily apparent to those skilled in the art, and the general principles defined herein may be applied to a wide range of embodiments. Thus, the subject matter disclosed herein is not intended to be limited to the embodiments presented, but is to be accorded the widest scope consistent with the principles and novel features disclosed herein.

In the description provided, numerous specific details are set forth in order to provide a more thorough understanding of the subject matter disclosed herein. It will, however, be apparent to one skilled in the art that the subject matter disclosed herein may be practiced without necessarily being limited to these specific details. In other instances, well-known structures and devices are shown in block diagram form, rather than in detail, in order to avoid obscuring the subject matter disclosed herein.

All the features disclosed in this specification (e.g., any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described herein with reference to the figures. It should be noted that the figures are only intended to facilitate the description of the features. The various features described are not intended as an exhaustive description of the subject matter disclosed herein or as a limitation on the scope of the subject matter disclosed herein. Additionally, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the Claims herein is not intended to invoke the provisions of 35 U.S.C. 112, Paragraph 6.

It is noted that, if used, the labels left, right, front, back, top, bottom, forward, reverse, clockwise and counterclockwise have been used for convenience purposes only and are not intended to imply any particular fixed direction. Instead, the labels are used to reflect relative locations and/or directions between various portions of an object.

Any data processing may include data buffering, aligning incoming data from multiple communication lanes, forward error correction (“FEC”), and/or others. For example, data may be first received by an analog front end (AFE), which prepares the incoming for digital processing. The digital portion (e.g., DSPs) of the transceivers may provide skew management, equalization, reflection cancellation, and/or other functions. It is to be appreciated that the process described herein can provide many benefits, including saving both power and cost.

Moreover, the terms “system,” “component,” “module,” “interface,” “model,” or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless explicitly stated otherwise, each numerical value and range may be interpreted as being approximate, as if the word “about” or “approximately” preceded the value of the value or range. Signals and corresponding nodes or ports might be referred to by the same name and are interchangeable for purposes here.

While embodiments may have been described with respect to circuit functions, the embodiments of the subject matter disclosed herein are not limited. Possible implementations may be embodied in a single integrated circuit, a multi-chip module, a single card, system-on-a-chip, or a multi-card circuit pack. As would be apparent to one skilled in the art, the various embodiments might also be implemented as part of a larger system. Such embodiments may be employed in conjunction with, for example, a digital signal processor, microcontroller, field-programmable gate array, application-specific integrated circuit, or general-purpose computer.

As would be apparent to one skilled in the art, various functions of circuit elements may also be implemented as processing blocks in a software program. Such software may be employed in, for example, a digital signal processor, microcontroller, or general-purpose computer. Such software may be embodied in the form of program code embodied in tangible media, such as magnetic recording media, optical recording media, solid-state memory, floppy diskettes, CD-ROMs, hard drives, or any other non-transitory machine-readable storage medium, that when the program code is loaded into and executed by a machine, such as a computer, the machine becomes an apparatus for practicing the subject matter disclosed herein. When implemented on a general-purpose processor, the program code segments combine with the processor to provide a unique device that operates analogously to specific logic circuits. Described embodiments may also be manifest in the form of a bit stream or other sequence of signal values electrically or optically transmitted through a medium, stored magnetic-field variations in a magnetic recording medium, etc., generated using a method and/or an apparatus as described herein.

Thermal imaging works by detecting heat, or infrared radiation (IR), emitted by objects and converting the detected IR into an electronic signal. This signal is then processed to produce a thermal image. Thermal imaging is a technology that converts thermal energy into visible light. Thermal cameras, also known as infrared cameras, capture the temperature profile of an area and display it as a heat map. Thus, thermal imaging is the process of converting IR into visible images that depict the spatial distribution of temperature differences in a scene viewed by a thermal camera. Thermal cameras detect different levels of infrared light, focus the infrared energy onto detectors, create a detailed pattern called a thermogram, and convert the thermogram to electrical signals to create a thermal image. Thermal imaging can see through materials such as plastic, smoke, dust, sand, rain, fog, darkness, walls, etc.

Thermal radiation (e.g., thermal energy) is electromagnetic radiation emitted from all matter that is at a non-zero temperature in the wavelength range from 0.1 μm to 100 μm. It includes part of the ultraviolet (UV), and all the visible and infrared. Thermal wavelengths are electromagnetic radiation emitted by objects with a non-zero temperature. They range from the longest infrared rays to the shortest ultraviolet rays. Thermal wavelengths include part of the ultraviolet (UV), and all the visible and infrared spectrum. Thermal radiation, or infrared radiation, is a band in the electromagnetic radiation spectrum with wavelengths above red visible light between 780 nm and 1 mm. The energy distribution of thermal radiation with wavelength is a function of the temperature of the source. Hotter objects have a shorter wavelength and cooler objects have a longer wavelength. Thermal sensors may include negative temperature coefficient (NTC) thermistors, resistance temperature detectors (RTDs), thermocouples, semiconductor-based sensors, and the like.

Thermal imaging cameras use an analog-to-digital converter (ADC) to convert thermal imaging signals into digital. The ADC quantifies the camera's signal in discrete steps that provide a temperature resolution. Temperature resolution describes how close two objects can be in temperature before they can no longer be distinguished. A thermal imaging system's performance depends on the sophistication of the signal processing algorithms and the design of the electronics. An infrared camera may include a sensor, a lens, and a digital signal processor (DSP). The DSP processes the thermal data collected by the sensor. DSPs are programmable microprocessors that processes digital data in real time. DSPs are used to improve or modify the quality of data streams.

Long-wave infrared (LWIR) is a part of the infrared spectrum that covers wavelengths from 8 to 15 micrometers (μm). It's a subset of the infrared band of the electromagnetic spectrum. Long-wave infrared or LWIR is a subset of the infrared band of the electromagnetic spectrum, covering the wavelengths ranging from 8 to 15 μm (8,000 to 15,000 nm). LWIR cameras are a type of thermal cameras that detect radiated temperatures. LWIR energy has much larger wavelengths than visible light. This means that physical sensor elements of LWIR cameras (e.g., pixels, photosensors, etc.) are generally larger than its standard visible light-detecting counterpart. LWIR lenses are infrared lenses that are optimized for use in the 8000-12000 nm range. They are typically uncooled and have less sensitivity, but they allow the user to see through dust or smoke. LWIR lenses are used for thermal imagery and provide a high degree of flexibility in frame frequency, user interface, and temperature. The visible light spectrum (VIS) is a segment of the electromagnetic spectrum that the human eye can view. More simply, the VIS range of wavelengths is called visible light. Typically, the human eye can detect wavelengths from 380 to 700 nanometers within the visible spectrum.

Some LWIR thermal cameras use zinc selenide (ZnSe) lenses, zinc sulfide (ZS) lenses, germanium (Ge) lenses, or arsenic selenide (As40Se60) lenses, also known as chalcogenide lenses (e.g., black diamond 6 (BD6) lenses). The thickness of zinc selenide and zinc sulfide lenses ranges from 1 to 25 millimeters (mm). The thickness of chalcogenide and germanium lenses ranges from 1 to 10 mm.

A microlens is a relatively small lens that is usually less than a millimeter in diameter. Some microlenses may be made of a variety of plastic materials, polymers, etc. Polymer microlens arrays (MLAs) are used in a variety of applications, including optical sensors, 3D displays, lighting devices, 4D light-fields. MLAs can increase the light collection efficiency of charged couple device (CCD) arrays. These arrays collect and focus light onto the photosensitive areas of the CCD.

Metamaterials are artificial materials that interact with light and other forms of energy in ways that are not found in nature. They are 3D structures made up of at least two different materials. Metamaterials are designed around unique micro- and nanoscale patterns or structures called “meta-atoms.” These structures provide optical properties that can be shaped on length scales below the wavelength of light. Metamaterials can affect sound waves, electromagnetic radiation, light, and even earthquakes in ways that bulk materials cannot. For example, metamaterials can transparently block a specific color of light, or heat a window in a car. Metasurfaces are nanopatterned structures that are ultrathin layers of metamaterials. They are made of human-engineered arrays of optical scatterers that are spaced subwavelength apart and placed on top of a flat surface. Metasurfaces can transmit or reflect light to focus and steer it, as well as perform other types of wave manipulation. They can also interact strongly with light, significantly changing the properties of light over a subwavelength thickness. Metasurfaces can be used in many applications, including anechoic chambers, scattering control, photodetectors, microbolometers, solar cells, microwave energy harvesting, sensor and radar cross-section reduction applications, etc.

An electromagnetic metasurface refers to a kind of artificial sheet material with subwavelength thickness. Metasurfaces can be either structured or unstructured with subwavelength-scaled patterns in the horizontal dimensions. In electromagnetic theory, metasurfaces modulate the behaviors of electromagnetic waves through specific boundary conditions rather than constitutive parameters in three-dimensional (3D) space, which is commonly exploited in natural materials and metamaterials. Metasurfaces may also refer to the two-dimensional counterparts of metamaterials. There are 2.5D metasurfaces that involve the third dimension as additional degree of freedom for tailoring their functionality.

A thin film semiconductor is a layer of semiconductor material that is grown or deposited on a substrate. Thin films are typically a few nanometers to microns thick. For example, thin films can range from a few atoms to 100 micrometers thick. A thin film layer that is less than 2 micrometers thick is considered relatively thin, while a thin film layer that is more than 20 micrometers is considered relatively thick. Thin films are made by growing or depositing layers of semiconductor material on a substrate using various deposition processes. Thin film deposition is the process of creating and applying thin film coatings to a substrate material. Deposition processes include vaporization and condensation (e.g., vaporize the solid material and condense it onto the substrate), gas or vapor reaction (e.g., the gas or vapor reacts with the substrate to create a solid thin film), thermal evaporation (e.g., deposit pure metals, non-metals, oxides, and nitrides), magnetron sputtering (e.g., use a physical phenomenon to expel microscopic particles of solid materials from their surface), physical vapor deposition (PVD), chemical vapor deposition (CVD), electron beam (e-beam) evaporation.

The coatings can be made of many different materials, such as metals, oxides, and compounds. In thin film deposition, material is added to the substrate in the form of thin film layers. These layers can be structural or act as spacers that can later be removed. Deposition techniques may control layer thickness within a few tens of nanometers. Thin film deposition can be done by processing above the substrate surface, typically a silicon wafer with a thickness of 200-700 μm.

Phase-modulating thin-film optics may use metasurfaces to modify the phase of electromagnetic radiation (e.g., light, heat). Such modifications may reduce aberrations, improve efficiency, alter the polarization of electromagnetic radiation, and change the field of view, among other benefits. Such phase-modulating thin-film optics may allow for optimization of a pixel array (e.g., image sensor array, heat sensor array, microbolometer array) at the individual sensor level, optimizing the electromagnetic radiation for a specific location or predetermined target wavelength.

Metamaterials are materials composed of multiple elements arrayed in patterns normally not found in nature. These patterns are typically of materials at the nanoscale or microscale, and may form a repeating pattern. Such patterns may also comprise a series of patterns, which may or may not repeat. The shape, geometry, size, orientation, and arrangement of the materials may produce a number of effects, especially on the surface of a thin film, also known as a metasurface. A metamaterial pattern may use elements and patterns having a size that varies within a fraction of a target wavelength. A metamaterial pattern can vary depending on the target wavelength. For example, if LWIR wavelengths are the target, then each unit cell size may vary between 1-3 microns to tens of microns. If VIS wavelengths are the target, then each unit cell size may vary between in the submicron range. As used herein, metamaterial and metasurfaces may be used interchangeably.

A metasurface thin film thus may use nanoscale and microscale elements to alter electromagnetic waves traveling through the thin film. By careful choice of patterns, a metasurface may create within the thin film layer local conditions within the thin film that alters the index of refraction, and thus alter the magnitude of interaction with electromagnetic radiation through the thin film. By doing so, phases of electromagnetic radiation passing through the thin film may be modulated. Due to some of the metasurface elements being subwavelength, the metasurface elements may produce changes at a much smaller size than conventional optics. Additionally, although refractive index is used herein, the refractive index changes here are related to the differences in the dielectric constant. As such, a high-index material will have a higher dielectric constant while a low-index material with have a lower dielectric constant.

Phase modulation is a process that changes the phase angle of a carrier wave to match a data signal. This adjustment allows for efficient data transmission over different mediums. Phase modulators may manipulate the phase of electromagnetic radiation (e.g., heat, light). Phase modulation of electromagnetic wavelengths may include focusing, steering, scattering, phase shifting, polarizing, etc.

A bolometer is a device that measures the power or heat of electromagnetic radiation. It works by detecting changes in the electrical resistance of certain materials when they absorb radiation. Bolometers can be used with a spectroscope to measure how well chemical compounds absorb different wavelengths of infrared radiation. Bolometers may include an absorber connected to a heat sink by an insulating link. The thermal link that connects the thermally active parts of the bolometer to the heat sink has low heat capacity and appropriate thermal conductivity. Bolometers have low heat capacity, low electrical noise, and adequate temperature dependence of their electrical resistance.

A microbolometer is a thermal detector that is used in thermal cameras. It is a type of bolometer that is made up of a grid of microscopic heat sensors (e.g., made of vanadium oxide or amorphous silicon). The sensors are placed on top of a grid of silicon. Microbolometers work by measuring the temperature of a material using a thermistor, which has a high temperature coefficient of resistance. They work on thermal principles, where an object's emitted infrared radiation is absorbed by a thermally insulated membrane. The membrane warms up due to the thermal insulation and absorption. Microbolometers convert an incoming optical signal into an electrical signal. The amplitude of the electrical signal is described by the term responsivity in relation to the incident flux. The microbolometer is typically composed of a large number of pixels, each of which has its own thermistor and readout circuit. By measuring the resistance of each thermistor, an infrared image can be created that shows the distribution of temperature across the scene being viewed. In some examples, a microbolometer may include one or more membrane regions and one or more bridge regions (e.g., semiconductor bridge, microbridge, bolometer bridge). A bridge region may include electronics, interconnections (e.g., copper interconnects), contacts, printed circuit board (PCB) routes, vias, circuitry (e.g., logic circuitry). In some cases, the bridge regions may be configured for, connected to, and/or include one or more readout integrated circuits.

In some examples, a thermal camera may include an array or grid of microbolometers (e.g., microbolometer sensor array). In some cases, each pixel of the thermal camera is based on a membrane of a microbolometer (e.g., each pixel includes at least one membrane). In some cases, each pixel of a microbolometer sensor array acts as a single sensor element. To ensure thermal isolation, such a microbolometer pixel may be formed based on a bolometer bridge. In some cases, the bolometer bridge may be coated with bolometer material. The cavity beneath the bolometer bridge may function as a resonator/absorber (e.g., λ/4-resonator/absorber). In some cases, a microbolometer sensor array may be under vacuum atmosphere for thermal isolation reasons. The temperature of the bolometer bridge changes due to the absorbed incident radiation. This temperature change affects the electrical resistance of the bolometer material due to its temperature coefficient of resistance (TCR).

Uncooled infrared sensors may use microbolometers as a sensor element for IR radiation. Such microbolometers work according to the thermal principle, in which the infrared radiation emitted by an object is absorbed by a thermally insulated membrane. This membrane heats up due to thermal insulation and absorption. Since this membrane contains a temperature-dependent resistance as a sensor layer, a change in the electrical resistance ultimately occurs, which is converted into a signal (e.g., a 16-bit signal) by the readout integrated circuit. In some examples, vanadium oxide and/or amorphous silicon may be used as sensor material.

A thermopile is an electronic device that converts thermal energy into electrical energy. It is made up of multiple thermocouples that are usually connected in series or in parallel. A thermopile works on the principle of the thermoelectric effect, generating a voltage when its dissimilar metals (thermocouples) are exposed to a temperature difference. Thermopiles are used for contactless temperature sensing. They can measure small temperature changes or generate thermoelectric current. Thermopiles work by transferring the heat radiation emitted from an object to a voltage output. Thermopiles are made up of a number of thermocouples that are connected in series to generate more millivoltage than a single thermocouple. Thermopile sensors may be based on bulk micromachining of complementary metal-oxide semiconductor (CMOS)-processed wafers, whereas microbolometers may be based on surface micromachining of the CMOS-processed wafers.

The chief ray angle (CRA) is the angle between the optical axis and the lens chief ray. The lens chief ray is the ray that passes through the aperture stop of the optical system and the line between the entrance pupil's center and the object point. The CRA affects image quality factors such as color shading and vignetting. The magnitude of impact from CRA mismatch can be approximated using the Difference of Squares. The CRA angle, as specified by the sensor manufacturer, is dependent on the construction of the sensor.

Mercury cadmium telluride (HgCdTe) is a semiconductor material that is used in thermal camera sensors. HgCdTe is also known as MCT (Mercury Cadmium Telluride). MCT detectors (MCT pixels) are semiconductors that absorb IR light and move electrons from the valence band to the conduction band. MCT detectors have a slightly higher percentage of dead pixels, which can affect the quality of the infrared image. HgCdTe is a pseudobinary alloy of CdTe and HgTe that crystallizes in a zincblende structure. The composition of Hg and Cd can be adjusted to tune the optical properties in the infrared region. HgCdTe is a common material in photodetectors of Fourier transform infrared spectrometers. This is because of the large spectral range of HgCdTe detectors and also the high quantum efficiency. It is also found in military field, remote sensing and infrared astronomy research.

A Quantum Well Infrared Photodetector (QWIP) is a semiconductor infrared photon detector that uses electronic intersubband transitions in quantum wells to absorb photons. QWIPs are high-performance, wavelength-selective IR detectors used in imaging, sensing, and other applications. A quantum well is a nanometer-thin layer that can confine (quasi-) particles in the dimension perpendicular to the layer surface. The movement in the other dimensions is not restricted.

Indium antimonide (InSb) is a crystalline compound made from indium and antimony. InSb is a narrow-gap semiconductor material used in infrared detectors, including thermal imaging cameras, forward looking IR (FLIR) systems, and infrared homing missile guidance systems. InSb has a high electron mobility and a unique lattice structure. InSb is sensitive to wavelengths between 1 and 5 mm. InSb is also used in the manufacture of electronic devices such as infrared detectors and sensors, as well as in high-speed electronic devices.

A type II superlattice (T2SL) is a photon detector that uses molecular beam epitaxy to create ultra-thin heterostructures. T2SLs are made from materials in group III-V (e.g., indium arsenide (InAs), gallium antimonide (GaSb)) and have an overlapping multiple-quantum well structure. A T2SL pixel is a small pixel pitch infrared detector that can serve 3-5 μm (MWIR) and 8-12 μm (LWIR) wavelength. T2SLs are a new technology for photonics that covers the spectral ranges of short-wavelength infrared (SWIR) to long-wavelength IR (LWIR). T2SLs are promising for space applications because they are less sensitive to cut-off wavelength variations and offer good homogeneity. One benefit of T2SLs is their ability to tune the detection cut-off wavelength over a wide range. T2SLs can also be used as mid- or long-wavelength infrared absorbers.

Ferromagnetic materials are substances that have a high magnetism in the same direction as the magnetic field. They are strongly attracted to magnets and can retain their magnetism for a relatively long time. For ferromagnetic material, the susceptibility decreases with temperature. The temperature of transition from ferromagnetic material to paramagnetic material is known as the Curie temperature. Temperature sensitive ferrite is a ferromagnetic material that has soft magnetic characteristic under its Curie temperature. The saturated magnetic flux density of temperature sensitive ferrite decreases as the material temperature increases, and the temperature sensitive ferrite becomes paramagnetic (lose its magnetic property) rapidly when the temperature of the material reaches its Curie temperature.

Giant magnetoresistance (GMR) is a quantum mechanical magnetoresistance effect observed in multilayers composed of alternating ferromagnetic and non-magnetic conductive layers. GMR sensors are a surface-based biosensing method that change their electrical resistance in response to changes in the local magnetic field. GMR sensors may be configured as thermal radiation detecting sensors. GMR sensors have a faster response time than conventional CMOS thermal sensors, which rely on electron diffusion. GMR sensors are also several times more precise than silicon Hall sensors over a wide range of temperature and supply voltages.

An interposer is a component used in electronics and semiconductor manufacturing. An interposer is an electrical interface that connects one socket or connection to another. Interposers may be custom designed to fit specific chip packages and a package substrate. Interposers may have a wider pitch than traditional connectors, which allows for easy rerouting of connections. The wide pitch also provides a larger channel for electrical signals, which reduces the amount of energy needed to transmit signals. Interposers may be used to connect different components or technologies that might not naturally interface with each other, spread a connection to a wider pitch, reroute a connection to a different connection, provide a mounting surface for semiconductor dies, enable connections to be formed between semiconductor dies, and/or connect the entire stack back to a packaging substrate.

Photoresist is a light-sensitive material that creates a patterned coating on a surface. It's made up of polymers, solvents, and sensitizers, each with a specific purpose. Photoresist is used in many processes, including photolithography, photoengraving, and photoresist etching. AZ photoresists are general purpose i-line/hline/g-line sensitive materials engineered for performance in electro-plating and other metal deposition process environments. Metasurfaces may be made from dielectric materials.

Off-chip components are discrete components that are not built on the integrated circuit (IC), microchip, or computer chip. Off-chip components may be located off-chip because the components may require a higher voltage level or power than the chip can handle. For example, off-chip components may include coils, capacitors, and resistors of relatively high values, etc.

Nanostructures (e.g., nanostructured patterns) are nanoscale structures created on the surface of a substrate. Nanopatterning is the process of creating these patterns, which may have at least one dimension that may be smaller than 100 nanometers. Nanostructures are materials with one dimension in the nanoscale range (<100 nm). Nanostructures can be made of a single material or multiple materials. Nanostructures can have different shapes, including spherical, triangular, rod, hexagonal, cubic, amorphous, needle-like, and crystalline.

An optical grating, also known as a diffraction grating, is an optical element that splits electromagnetic radiation (e.g., heat, light) into multiple beams that move in different directions. Optical gratings may be made up of parallel lines or grooves that are engraved on a surface. The simplest type of grating has many evenly spaced parallel slits. When polychromatic light hits the grating, each wavelength of light is reflected at a slightly different angle. For example, red light is bent further than blue light because red light has a longer wavelength. Thus, diffraction grating breaks up the colors of white light. Diffraction gratings are used in many scientific and technological applications. Diffraction gratings are typically better than prisms because they are more efficient, give a linear dispersion of wavelengths, and are free of absorption effects. Diffraction gratings work for both transmission and reflection of electromagnetic radiation. Examples of natural diffraction gratings include butterfly wings, the Australian opal, and the feathers of some birds like hummingbirds. Diffraction gratings may include binary gratings and/or blazed gratings.

Binary gratings may include a periodic structure that causes optical amplitude and/or phase changes. A binary grating may include a periodic structure that has a binary change in phase or amplitude within a single period. A binary grating is a periodic structure with binary change in amplitude or phase within one period. Binary line gratings are often used in spectrometers. Binary gratings may have grating periods greater than one wavelength, but use subwavelength structures within one period. This allows binary gratings to achieve high efficiencies of 70-80%. Binary phase gratings are similar to binary amplitude gratings, but the opaque regions are replaced by etched grooves. Diffraction gratings separate the wavelength components of electromagnetic radiation (e.g., heat, light) by directing each wavelength into a unique output angle. Diffraction gratings such as binary gratings are commonly used in monochromators and spectrometers, but also have other applications such as optical encoders and wavefront measurement. Binary line gratings can diffract electromagnetic radiation in several directions due to the symmetry of the structure, whereas blazed and slanted gratings may diffract in a single direction.

Blazed gratings are a type of diffraction grating optimized for maximum efficiency in a given diffraction order. Blazed gratings are also known as echelette gratings or saw-tooth gratings. Blazed gratings have a triangular, sawtooth-shaped cross section, forming a step structure. The steps are tilted at the blaze angle with respect to the grating surface. The blaze angle is optimized to maximize efficiency for the wavelength of the used light. Blazed gratings operate at a specific wavelength, known as the blaze wavelength. This means that the majority of the optical power will be in the designed diffraction order while minimizing power lost to other orders. Blazed gratings are relatively efficient and are a good choice for applications with high signal strength constraints.

Fill factor of an image sensor is the ratio of light-sensitive area of a pixel to total pixel area in an image sensor. A higher fill factor means the sensor is more sensitive to light (e.g., more efficient). Fill factor ratios vary by device, but generally range from 30-80% of the pixel area. A lower fill factor means the sensor is less sensitive and requires longer exposure times.

Numerical aperture (NA) is a dimensionless number that measures the range of angles at which an optical system can accept or emit light. NA is a theoretical parameter based on geometrical considerations and is calculated from the optical design. NA is a measure of the collection efficiency of an optical system. NA directly related to the angle of the cone between a point on the specimen and the front lens of the objective or condenser. The larger the NA, the more light can enter the lens, and the more detail can be resolved. When more light enters the lens, the image becomes brighter. In a single lens, NA is proportional to the optics diameter and inversely proportional to the focal length. For light microscopes, the NA is ˜1. For electron microscopes, the NA is ˜0.01.

A hole-based thin film is a thin film with an array of micrometer-sized holes. The holes change the stress distribution of the material, so that cracks only form at specific points near the edges of the holes. A hole is a void area where there is no coating. Electromagnetic radiation (e.g., infrared, thermal) may travel unimpeded through such holes. A hole-based metalens uses an array of nanometer- and/or micrometer-sized holes to modulate electromagnetic radiation (e.g., focus, steer, scatter, phase shift, polarize infrared wavelengths).

A pillar-based thin film is a thin film with a microstructure made of isolated vertical pillars. Thin films are layers of material deposited on a bulk substrate to give the substrate properties that can't easily attain on its own. Thin films are used in a variety of surface coatings to alter opto-electronic properties or increase wear or corrosion resistance. A pillar-based metalens may include a surface with a semiconductor layer. The semiconductor may be etched with an array of pillars that are nanometers to tens of microns high.

Components for thermal imaging are bulky and expensive (e.g., Ge, ZnSe, ZnS, BD6, etc.). Metasurfaces designed for the long-wave infrared (LWIR) range allow phase modulation of thermal wavelengths (focusing, steering, scattering, etc.). Thickness of metasurfaces for LWIR as described herein can be in the range of around 10 μm, which makes metasurfaces up to 1000× thinner and significantly lighter than other thermal lenses.

The techniques described herein include logic to provide phase modulating thin film for long-wave infrared thermal imaging. The logic includes any combination of hardware (e.g., at least one memory, at least one processor), logical circuitry, firmware, and/or software to provide phase modulating thin film for long-wave infrared thermal imaging.

The techniques described herein include an array that includes an array of pixels and a phase modulating thin film. In some examples, the pixels may include thermal radiation detecting sensors such as microbolometers, thermopiles, HgCdTe, mercury cadmium telluride (MCT), quantum well (QWIP), InSb, and type II superlattice (T2SL), ferromagnetic, giant magneto resistance (GMR), etc.

In some examples, the phase modulating thin film may include low refractive index nanometer structures, low refractive index micrometer structures, high refractive index nanometer structures, high refractive index micrometer structures, binary gratings, and/or a liquid crystal with one or more layers. For example, a thin film (e.g., phase modulating thin film) may include at least one of low refractive index nanometer structures at least at a first portion of the thin film, low refractive index micrometer structures at least at a second portion of the thin film, high refractive index nanometer structures at least at a third portion of the thin film, high refractive index micrometer structures at least at a fourth portion of the thin film, and/or binary gratings at least at a fifth portion of the thin film. In some examples, the phase modulating thin film may include at least one thin film layer and at least one liquid crystal layer. In some cases, a liquid crystal layer (e.g., configured above or below a thin film layer relative to incident heat or light) may include a top transparent electrode above liquid crystals (e.g., above being closer to incident heat or light relative to the liquid crystals), the liquid crystals, and a bottom transparent electrode below the liquid crystals (e.g., below being farther from incident heat or light relative to the liquid crystals).

In some cases, the phase modulating thin film includes a relatively high aspect ratio (height/diameter) dielectric nanostructures (e.g., low and/or high dielectric nanostructures) embedded in a dielectric medium (e.g., low and/or high dielectric medium). In some examples, the phase modulating thin film may be configured to focus, deflect, guide, bend, and/or route thermal radiation. In some cases, the phase modulating thin film includes an antireflective surface. The antireflective surface may be a series of dielectric or organic materials such as photoresists, electron-beam resists, germanium, zinc selenide, zinc-sulfide, etc. In some cases, the phase modulating thin film may provide up to a 2Pi radian phase shift. The phase profile of the phase modulating thin film may vary spatially within a pixel. In some cases, the phase profile of the phase modulating thin film may vary spatially across the pixel arrays.

The phase modulating thin film may include a structure/surface with one or more layers. In some cases, the phase modulating thin film may include a structure/surface with two or more different materials. In some examples, the phase modulating thin film may focus the incoming heat with predefined focal length. In some cases, the phase modulating thin film may partially or completely cover the pixel area.

The techniques described herein include multiple advantages and benefits. Unlike bulky and expensive components of some thermal cameras, the present techniques significantly reduce the size and expense of thermal imaging components. For example, phase modulating thin films for LWIR are in the range of around 10 μm in thickness, which makes phase modulating thin film lenses up to 1000× thinner and significantly lighter than other thermal lenses. Also, phase modulating thin films designed for LWIR range allow phase modulation of thermal wavelengths (focusing, steering, scattering, etc.). Also, phase modulating thin film lenses for thermal imaging provide up to a 2Pi radian phase shift. Accordingly, phase modulating thin film lenses for thermal imaging may be optimized for a variety of chief ray angles (CRAs).

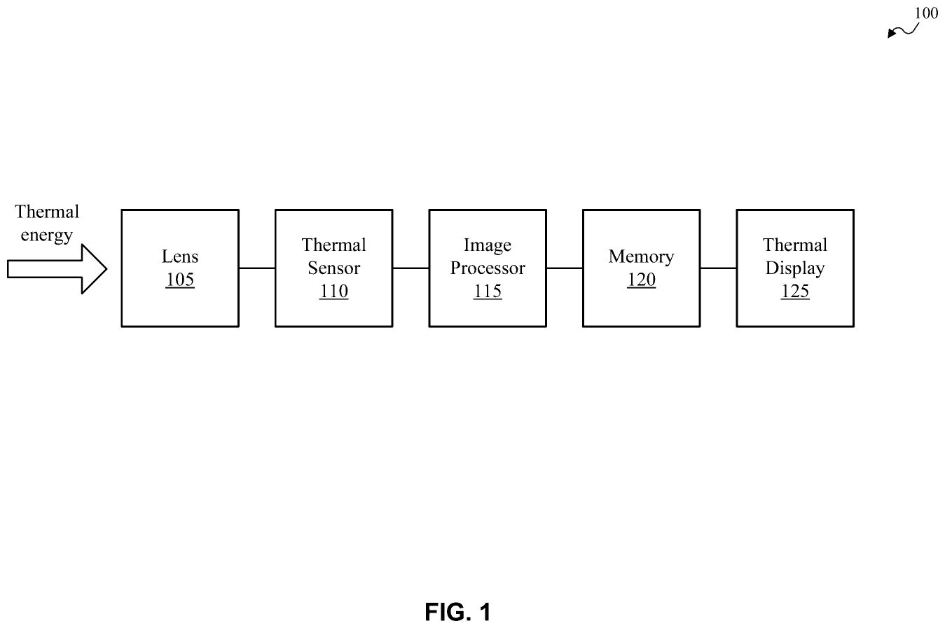

FIG. 1 illustrates an example thermal imaging system 100 in accordance with one or more implementations as described herein. According to the illustrated example, thermal imaging system 100 may include lens 105, infrared (IR) sensor 110, image processor 115, memory 120, and thermal display 125.

In one or more examples, lens 105 may be configured to focus, deflect, guide, bend, and/or route incident thermal energy (e.g., thermal radiation) onto thermal sensor 110. In some cases, lens 105 may include a filter configured to allow one or more selected spectral bands to pass while blocking other spectral bands.

In some implementations, thermal sensor 110 may be configured to detect thermal energy and convert the thermal energy to an electrical signal. In some cases, thermal sensor 110 may include a cooling system that chills image sensors (e.g., thermal sensor 110) to reduce thermally-induced noise below the level of the imaging signal at the scene being detected.

In some examples, image processor 115 may be configured to process thermal image data (e.g., thermal image processor). In some examples, image processor 115 may include an ADC to detect and convert thermal energy detected by thermal sensor 110 to a digital signal. In some cases, thermal sensor 110 may include a DSP to process the digital signal. In some examples, image processor 115, in conjunction with memory 120, may record temperatures of objects in a captured frame and assign each temperature a color. For example, image processor 115 may assign a relatively cold temperature as purple, a moderate temperature as red, and a relatively hot temperature as yellow. In some cases, the maximum hottest objects detectable by the thermal imaging system 100 may appear white, while the coldest objects may appear dark blue or black.

In one or more examples, memory 120 may be configured to store data generated by thermal sensor 110 and/or data processed by image processor 115. In some examples, memory 120 includes DRAM to store thermal image data (e.g., the electrical signal of the IR sensor, the digital signal of the image processor 115, etc.). Additionally, or alternatively, memory 120 includes cache memory (e.g., SRAM) to hold data being processed by image processor 115.

In some cases, thermal display 125 may be configured to display the relative temperature of objects detected by thermal sensor 110 and processed by image processor 115. In some examples, thermal display 125 may be configured to show objects detected by thermal sensor 110 and processed by image processor 115 based on the color assigned to each object according to the detected temperature of each object.

It is noted that some thermal cameras are equipped with only a global lens (e.g., no microlens). In some cases, a microlens process may not be compatible with thermal image sensors due to the relatively large pixel sizes and the high absorption of LWIR wavelength in polymers. HgCdTe detectors (cooled) are equipped with hyperspherical lens array to improve resolution and efficiency, but these are bulky, which reduces resolution significantly. There are some lenses (e.g., 25 μm macrolens) that improve thermal imaging resolution, but they typically have limited focal length and are enclosed in a thick case for off-chip mounting.

Table 1 shows the properties of various materials. Table 1 indicates data based on type of material (e.g., (pillar, substrate), lens type (e.g., circular or square metalens, diffractive), associated wavelength, focusing efficiency, numerical aperture (NA), size (e.g., diameter), and use (e.g., features, purpose, etc.). AZ shows high absorption (25% within material) because of non-zero k. Si/Si metalenses report low efficiency even though k=0 because of high refractive index that induces reflection on backside (reflection 29%). Improvement may be made with anti-reflection coating on polished backside of Si wafer. With a perfect anti-reflection coating, Si metalens efficiency is estimated to be around 50%.

TABLE 1

| | | Wave- | Focusing | | Size | |
|---|---|---|---|---|---|---|
| Material | Type | length | Efficiency | NA | (Diam.) | Use |
| Si/Si | Meta | 10.6 μm | 35% | 0.6 | 12 mm | High NA, |
| | (Circular) | | | | | polarization |
| | | | | | | insensitive |
| Si/Si | Meta | 10.6 μm | 34% | 0.45 | 0.1 mm per | Replacing |
| | (Circular) | | (43% | | microlens, | microlenses |
| | | | simulated) | | 6 mm total | |
| Si/Si | Meta | 8-12 μm | Not | 0.45 | 2 cm | Thermal |
| | (Square) | | reported | | | imaging via |
| | | | | | | all-silicon |
| Si/Si | Meta | 8-14 μm | Not | 0.1 | 60 μm | For |
| | (Circular) | | reported | | | increasing |
| | | | (T: 80% | | | fill factor |
| | | | simulated) | | | |
| AZ/AZ | Diffractive | 8-12 μm | 43-65% | 0.37-0.45 | 8-15.2 mm | Broadband |
| | (multi-level) | | | | | |
| Ge/Si | Meta | 9.07 μm | T: 97.5% | 0.32 | 8 mm | High transmission |
| | (Circular | | Focusing | | | using Ge AR coating |
| | hole) | | efficiency: 75% | | | |
| | | | (simulated) | | | |

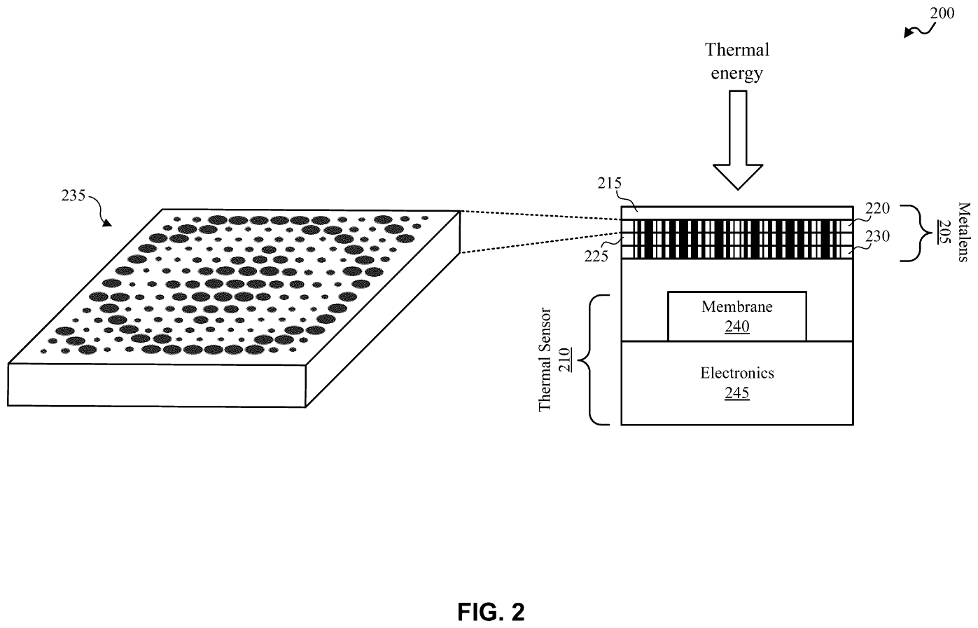

FIG. 2 illustrates details of thermal imaging system 100 of FIG. 1, according to examples described herein. FIG. 2 depicts thermal imaging system 200 (e.g., a side view of thermal imaging system 200). In the illustrated example, thermal imaging system 200 includes metalens 205 and thermal sensor 210. Metalens 205 may be an example of lens 105 of FIG. 1. Thermal sensor 210 may be an example of thermal sensor 110 of FIG. 1. In some cases, thermal imaging system 200 may be part of a thermal camera for capturing the temperature profile of an object and displaying the temperature profile as a heat map. Thus, thermal imaging system 200 may be one element (e.g., one thermal detection pixel) of a thermal camera, where thermal energy incident upon metalens 205 is converted into electrical signals by thermal sensor 210, where an image processor (e.g., image processor 115) converts the electrical signals into a thermogram displayed on a thermal display (e.g., thermal display 125).

In the illustrated example, metalens 205 includes antireflective surface 215 and one or more phase modulating thin film layers (e.g., first thin film layer 220, second thin film layer 225, and third thin film layer 230). In some cases, metalens 205 may be configured with less or more thin film layers (e.g., one thin film layer, two thin film layers, more than three thin film layers, such as up to ten thin film layers, etc.). In some examples, antireflective surface 215 may include at least one of a dielectric material, a photoresist, an electron-beam resist, germanium, or zinc selenide.

Thermal imaging system 200 illustrates an example configuration of phase modulating thin film (e.g., first thin film layer 220, second thin film layer 225, and third thin film layer 230) for long-wave infrared thermal imaging. The illustrated phase modulating thin film provides a designed phase shift in LWIR that controls focus, aberration, polarization, field of view (FOV), deflection, routing, bending, guiding, etc., of long-wave infrared waves or thermal radiation. The depicted phase modulating thin films can be optimized for any pixel size and any focal length, unlike other thermal lenses that have limited size and focal length due to curvature constraints. The depicted phase modulating thin films can be either off-chip, mounted over, or on-chip and directly integrated onto thermal image sensors. The depicted phase modulating thin films for LWIR may have a thickness around 10 μm (e.g., 5-20 μm), enabling management of thermal wavelengths in the micron scale.

As shown, first thin film layer 220 include nanostructures 235. Nanostructures 235 may be configured to modulate the phase of thermal energy incident on metalens 205. In some cases, nanostructures 235 may include at least one low refractive index nanostructure element (e.g., a nanostructure that provides a low index of refraction), at least one high refractive index nanostructure element, or a combination of the at least one low refractive index nanostructure element and the at least one high refractive index nanostructure element. In some cases, nanostructures 235 may include a pattern of low and/or high refractive index nanostructure elements.

In some examples, nanostructure 235 may include nanostructured elements that include at least one of a hole through first thin film layer 220, a pillar extending from a bottom surface of first thin film layer 220 (e.g., surface away from incident thermal radiation, surface further from antireflective surface 215), or diffraction grating on at least one of a top surface or the bottom surface of the first thin film layer 220. In some cases, a diameter of a hole or a pillar of nanostructure 235 may range between 100 micrometers and 1 nanometer. As shown, second thin film layer 225 and/or third thin film layer 230 may include nanostructures similar to first thin film layer 220.

In the illustrated example, thermal sensor 210 may include membrane 240 and electronics 245. In some examples, membrane 240 and electronics 245 may be components of a microbolometer (e.g., thermal sensor 210 configured as a microbolometer), where the microbolometer may include one or more membranes (e.g., membrane 240) and one or more bolometer bridges (e.g., bolometer bridges included in electronics 245). In some examples, thermal sensor 210 may be configured as a microbolometer, a thermopile, a mercury cadmium telluride sensor, a quantum well infrared sensor, an indium antimonide sensor, a type II superlattice sensor, a ferromagnetic sensor, or a giant magneto resistance sensor of the thermal camera.

In some examples, electronics 245 may include one or more bridge regions (e.g., semiconductor bridge, microbridge, bolometer bridge). Additionally, or alternatively, electronics 245 may include interconnections (e.g., copper interconnects), contacts (e.g., metal pads), printed circuit board (PCB) routes, vias, circuitry (e.g., logic circuitry, logic chips). In some cases, electronics 245 may be configured for, connected to, and/or include one or more readout integrated circuits for reading out electrical signals generated by thermal sensor 210.

In one or more examples, metalens 205 may be one metalens of an array of metalenses (e.g., a metalens array of a thermal camera, such as thermal imaging system 100). Similarly, thermal sensor 210 may be one thermal sensor of an array of thermal sensors (e.g., an array of thermal sensor pixels). In some examples, each metalens of the metalens array may be positioned over at least a portion of a thermal sensor of the thermal sensor array. As shown, metalens 205 is integrated with thermal sensor 210. It is noted that metalens 205 may be mounted off-chip (e.g., separate from thermal sensor 210), mounted over thermal sensor 210, or directly integrated on thermal sensor 210 as shown. In some cases, a second metalens of the metalens array may be mounted off-chip (e.g., separate from a second thermal sensor of the thermal sensor array), mounted over the second thermal sensor, or directly integrated on second thermal sensor. In some cases, one or more metalenses of the metalens array (e.g., at least metalens 205) may be integrated on an interposer and/or a thermal sensor such as thermal sensor 210.

In one or more examples, first thin film layer 220, second thin film layer 225, and third thin film layer 230 may be made of one or more refractive index materials. For example, at least one of first thin film layer 220, second thin film layer 225, or third thin film layer 230 may be formed with at least one low refractive index material, at least one high refractive index material, or a combination of the at least one low refractive index material and the at least one high refractive index material. In some examples, the at least one low refractive index material may be based on material with a refractive index of around n=1 to n=1.5. In some cases, the at least one high refractive index material may be based on material with a refractive index of n>1.5.

In one or more examples, nanostructure 235 may be configured to route thermal radiation incident upon metalens 205 to membrane 240 of thermal sensor 210. In some cases, nanostructure 235 may be configured to modulate a phase of thermal radiation incident on metalens 205. In implementations, nanostructure 235 may be configured to allow thermal radiation with wavelengths between 8 and 15 micrometers to pass through the first metalens (e.g., configured for LWIR). In some examples, nanostructure 235 of the first metalens may be configured to deflect thermal radiation with wavelengths below 7 or below 8 micrometers and/or deflect thermal radiation with wavelengths above 15 or above 16 micrometers (e.g., deflect or block transmission of wavelengths other than LWIR wavelengths through metalens 205).

In one or more examples, metalens 205 may include at least one embedded liquid crystal layer. Accordingly, metalens 205 may include at least one liquid crystal layer and one or more layers of dielectric and/or organic materials (e.g., photoresists, electron-beam resists, germanium, zinc selenide, etc.). In some cases, nanostructure 235 of metalens 205 provides up to a 2Pi phase shift of thermal radiation incident upon metalens 205.

Based on nanostructure 235, a phase modulation of metalens 205 may vary from a phase modulation of a second metalens of the metalens array. For example, based on nanostructure 235 of metalens 205 and/or a nanostructure of the second metalens, the phase modulation of metalens 205 may vary spatially across a first pixel (e.g., thermal sensor 210 of the thermal sensor array) compared to the phase modulation of the second metalens across a second pixel (of the thermal sensor array). For instance, for a given chief ray angle, metalens 205 may provide a phase modulation that varies from a phase modulation provided by the second metalens. In some examples, the varying phase modulation may be based on a nanostructure of metalens 205 varying from a nanostructure of the second metalens. Additionally, or alternatively, based on nanostructure 235, a phase modulation of metalens 205 may match or provide relatively the same phase modulation of a third metalens of the metalens array.

In one or more examples, a metalens array (e.g., that includes metalens 205) may be configured as a global lens of a thermal camera (e.g., thermal imaging system 100, thermal imaging system 200). Based at least on nanostructure 235, a phase profile of each metalens of the metalens array (e.g., including metalens 205) may be configured to vary spatially across the thermal sensor array.

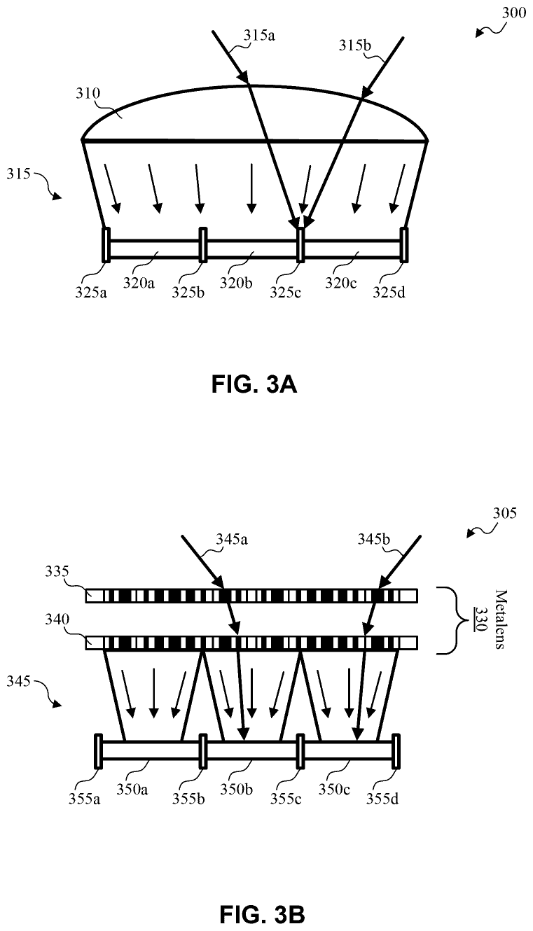

FIG. 3A illustrates an example system 300 in accordance with one or more implementations as described herein. In some examples, system 300 may be part of a thermal imaging system. As shown, system 300 includes a global lens 310, membranes 320 (e.g., membrane 320a, membrane 320b, membrane 320c) electronics 325 (e.g., electronics 325a, electronics 325b, electronics 325c, electronics 325d, which may include bolometer bridges, etc.). Global lens 310 may deteriorate thermal imaging resolution due to its limited curvature. As shown, global lens 310 guides incident thermal energy 315 towards membranes 320. However, due to the nature of global lens 310, some of the incident thermal energy 315 is guided towards electronics 325. For example, incident thermal energy 315a and incident thermal energy 315b, of different chief ray angles, are directed towards electronics 325c.

FIG. 3B illustrates an example system 305 in accordance with one or more implementations as described herein. In some examples, system 305 depicts a side view of a portion of a thermal imaging system, such as thermal imaging system 100 of FIG. 1 and/or thermal imaging system 200 of FIG. 2. As shown, system 305 includes metalens 330, membranes 350 (e.g., membrane 350a, membrane 350b, membrane 350c) electronics 355 (e.g., electronics 355a, electronics 355b, electronics 355c, electronics 355d). Metalens 330 may be an example of metalens 205 of FIG. 2. Membranes 350 may be an example of membrane 240 of FIG. 2. Electronics 355 may be an example of electronics 245 of FIG. 2. In some examples, each of the depicted membranes 350 between electronics 355 may be separate membranes (e.g., separate membrane regions of a microbolometer).

As shown, metalens 330 includes phase modulating thin film 335 and phase modulating thin film 340. In the illustrated example, phase modulating thin film 335 and phase modulating thin film 340 may be engineered to focus LWIR wavelength thermal energy into membranes 350 of micrometer pixel size (e.g., each membrane segment can be as small as 10 μm pixel size), which greatly improves thermal energy efficiency and resolution.

As depicted, phase modulating thin film 335 is spaced apart from phase modulating thin film 340 (e.g., spaced 1 to 20 μm apart). Alternatively, phase modulating thin film 335 may be placed positioned next to (e.g., formed on) phase modulating thin film 340. In some cases, the spacing between and/or the placing the one on the other may provide additional phase modulation, in addition to the phase modulation from the nanostructures of phase modulating thin film 335 and the phase modulation from the nanostructures of phase modulating thin film 340. For example, phase modulating thin film 335 may be designed to serve as a global lens and phase modulating thin film 340 may be designed to serve as an array of microlenses that match the pixel size of thermal imaging sensor.

In the illustrated example, metalens 330 guides incident thermal energy 345 towards membranes 350 (e.g., towards each segment of membranes 350), focusing incident thermal energy 345 onto the center of each membrane segment and steering incident thermal energy 345 away from electronics 355 (e.g., away from each segment of electronics 355). For example, metalens 330 may guide incident thermal energy 345a towards one membrane segment of membranes 350 (e.g., membrane 350b) and guide incident thermal energy 345b towards another membrane segment of membranes 350 (e.g., membrane 350c), guiding each away from electronics 355 and focusing towards the center of each membrane segment.

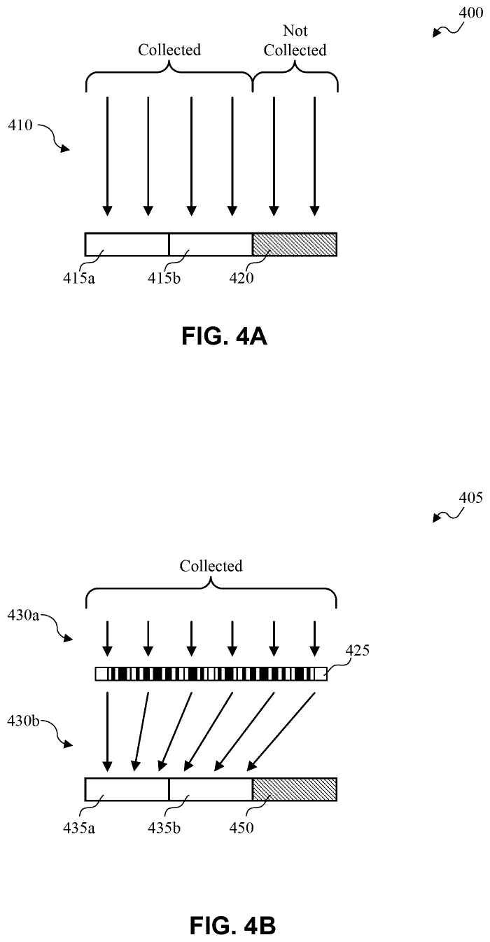

FIG. 4A illustrates an example system 400 in accordance with one or more implementations as described herein. In some examples, system 400 may be part of a thermal imaging system. As shown, system 400 includes membrane 415a and membrane 415b (e.g., of a membrane array of a thermal camera), and electronics 420.

System 400 may include a global lens (e.g., global lens 310 of FIG. 3A). As a result, thermal energy 410 incident on system 400 passes through the global lens and falls indiscriminately amongst membrane 415a, membrane 415b, and electronics 420. As a result, a portion of thermal energy 410 is not captured by the membrane array of system 400 (including membrane 415a and membrane 415b), but instead a portion of thermal energy 410 is lost on electronics 420. As a result, system 400 provides a relatively low fill factor and manifests the inefficiencies of thermal cameras that use a global lens.

FIG. 4B illustrates an example system 405 in accordance with one or more implementations as described herein. In some examples, system 405 depicts a side view of a portion of a thermal imaging system, such as thermal imaging system 100 of FIG. 1 and/or thermal imaging system 200 of FIG. 2. System 405 illustrates an example configuration of phase modulating thin film for long-wave infrared thermal imaging (e.g., thermal phase modulating thin film).

As shown, system 405 includes metalens 425 (e.g., based on a phase modulating thin film), membrane 435a and membrane 435b (e.g., of a membrane array), and electronics 450 of a thermal imaging system. Metalens 425 may be an example of metalens 205 of FIG. 2 and/or metalens 330 of FIG. 3B. Membrane 435a and/or membrane 435b may be examples of membrane 240 of FIG. 2 and/or membranes 350 of FIG. 3B.

Based on metalens 425, incident thermal energy 430a passes through metalens 425 and metalens 425 produces phase modulated thermal energy 430b, where phase modulated thermal energy 430b is guided by metalens 425 towards membranes 435a and membrane 435b, and away from electronics 450. As shown, system 405 improves efficiency based on spatially controlled focusing of thermal energy (e.g., phase modulated thermal energy 430b) to increase fill factor based on the thermal phase modulating properties of metalens 425.

As noted herein, a thermal camera pixel (e.g., thermal radiation detecting sensor such as a microbolometer) may include at least one membrane (e.g., membrane 415a and/or membrane 415b) and bridge/metal contact regions (e.g., electronics 450). As shown, metalens 425 is configured to direct incoming wavelengths (e.g., LWIR wavelengths) to a membrane region (e.g., membrane 415a, membrane 415b, etc.), thus increasing the fill factor of system 405 (e.g., increasing the efficiency of the thermal camera). As a result, a relatively high portion of thermal energy 430 (e.g., 90-100%) is captured by the membranes of system 405 (e.g., including membrane 415a and membrane 415b). Accordingly, system 400 provides a relatively high fill factor and manifests the energy-collecting efficiencies of implementing a metalens array in a thermal camera.

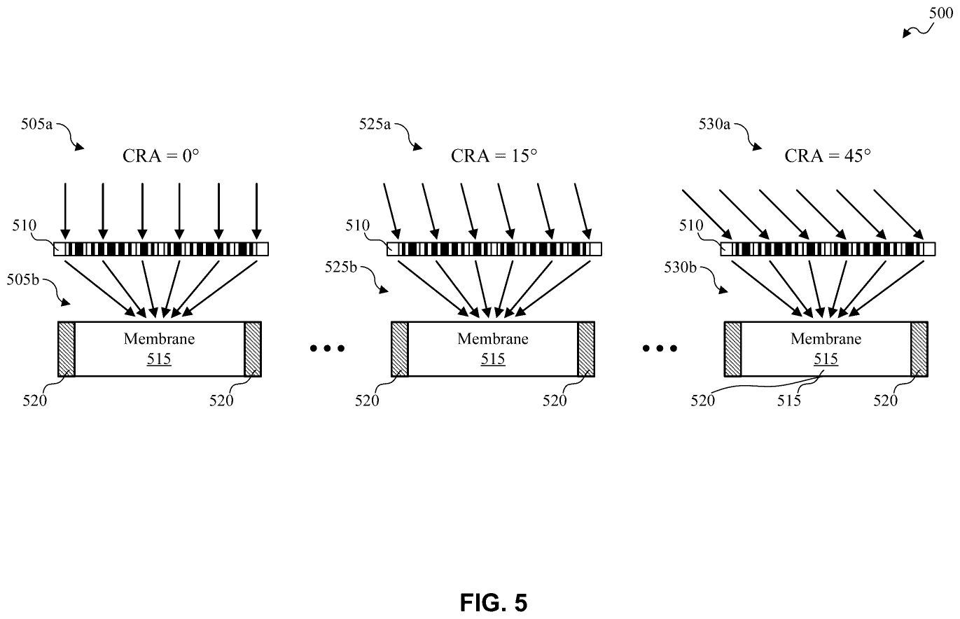

FIG. 5 illustrates an example system 500 in accordance with one or more implementations as described herein. System 500 illustrates an example configuration of phase modulating thin film for long-wave infrared thermal imaging. In some examples, system 500 depicts a side view of a portion of a thermal imaging system, such as thermal imaging system 100 of FIG. 1 and/or thermal imaging system 200 of FIG. 2.

As shown, system 500 includes metalens 510, membrane 515, and electronics 520. Metalens 510 may be an example of metalens 205 of FIG. 2, metalens 330 of FIG. 3B, and/or metalens 425 of FIG. 4B. Membrane 515 may be an example of membrane 240 of FIG. 2 membranes 350 of FIG. 3B, membrane 435a of FIG. 4B, and/or membrane 435b of FIG. 4B. Electronics 520 may be an example of electronics 245 of FIG. 2, electronics 355 of FIG. 3B, and/or electronics 450 of FIG. 4B.

As shown, metalens 510 may be optimized for a variety of chief ray angles (CRAs). A metalens based on phase modulating thin films (e.g., metalens 510) improves field of view (FOV) by optimizing for a wide range of CRAs. Some thermal global lenses (e.g., global lens 310) have limited curvatures, which limit their FOV. The FOV of some global lens thermal cameras is limited to 1.92×1.44 μm due to extreme lens curvature of the global lens. As shown, phase modulating thin films may be optimized for a variety of CRAs depending on the desired FOV or spatial location of each thermal imaging pixel (e.g., no limitation in size).

As shown, based on metalens 510, incident thermal energy 505a with a CRA of zero degrees passes through metalens 510 and metalens 510 produces phase modulated thermal energy 505b, where phase modulated thermal energy 505b is guided by metalens 510 towards membrane 515, and away from electronics 520.

Similarly, based on metalens 510, incident thermal energy 525a with a CRA of 15 degrees passes through metalens 510 and metalens 510 produces phase modulated thermal energy 525b, where phase modulated thermal energy 525b is guided by metalens 510 towards membrane 515, and away from electronics 520.

Similarly, based on metalens 510, incident thermal energy 530a with a CRA of 45 degrees passes through metalens 510 and metalens 510 produces phase modulated thermal energy 530b, where phase modulated thermal energy 530b is guided by metalens 510 towards membrane 515, and away from electronics 520.

As a result, system 500 improves efficiency based on spatially controlled focusing of thermal energy (e.g., phase modulated thermal energy 505b, 525b, and/or 530b) independent of the incident chief ray angle of incoming thermal energy, thus increasing fill factor based on the thermal phase modulating properties of metalens 510.

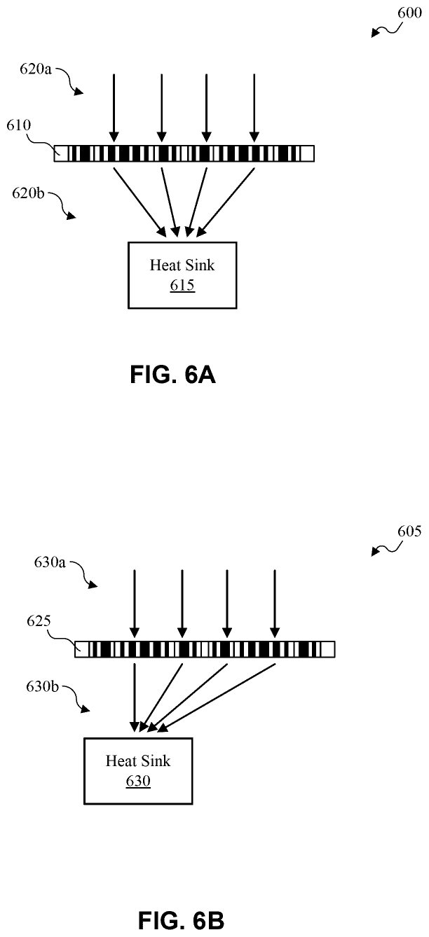

FIG. 6A illustrates an example system 600 in accordance with one or more implementations as described herein. System 600 illustrates an example configuration of phase modulating thin film for long-wave infrared thermal imaging. In some examples, system 600 depicts a side view of a portion of a thermal imaging system, such as thermal imaging system 100 of FIG. 1 and/or thermal imaging system 200 of FIG. 2.

As shown, system 600 includes metalens 610 and heat sink 615. Metalens 610 may be an example of metalens 205 of FIG. 2, metalens 330 of FIG. 3B, metalens 425 of FIG. 4B, and/or metalens 510 of FIG. 5. System 600 depicts heat sink 615 in relation to metalens 610, where metalens 610 is configured for routing heat (e.g., based on one or more phase modulating thin film of metalens 610).

In the illustrated example, based on metalens 610, incident thermal energy 620a passes through metalens 610 and metalens 610 produces phase modulated thermal energy 620b, where phase modulated thermal energy 620b is guided by metalens 5610 towards heat sink 615.

As shown, system 600 may be optimized for efficient heat routing. For example, a metalens based on microscale and/or nanoscale thermal phase modulating thin film (e.g., metalens 610) can be optimized for efficient heat routing. Using a metalens that implements phase modulating thin films (e.g., in a thermal camera) improves thermal management in the micron scale by enabling efficient steering of LWIR wavelengths.

FIG. 6B illustrates an example system 605 in accordance with one or more implementations as described herein. System 605 illustrates an example system of phase modulating thin film for long-wave infrared thermal imaging. In some examples, system 605 depicts a side view of a portion of a thermal imaging system, such as thermal imaging system 100 of FIG. 1 and/or thermal imaging system 200 of FIG. 2.

As shown, system 605 includes metalens 625 and heat sink 630. Metalens 625 may be an example of metalens 205 of FIG. 2, metalens 330 of FIG. 3B, metalens 425 of FIG. 4B, metalens 510 of FIG. 5, and/or metalens 610 of FIG. 6A. System 605 depicts heat sink 630 in relation to metalens 625, where metalens 625 is configured for routing heat (e.g., based on one or more phase modulating thin film of metalens 625).

In the illustrated example, based on metalens 625, incident thermal energy 630a passes through metalens 625 and metalens 625 produces phase modulated thermal energy 630b, where phase modulated thermal energy 630b is guided by metalens 5610 towards heat sink 630.

As shown, system 605 may be optimized for efficient heat routing. For example, a metalens based on microscale and/or nanoscale thermal phase modulating thin film (e.g., metalens 625) can be optimized for efficient heat routing. Using a metalens that implements phase modulating thin films (e.g., in a thermal camera) improves thermal management in the micron scale by enabling efficient steering of LWIR wavelengths.

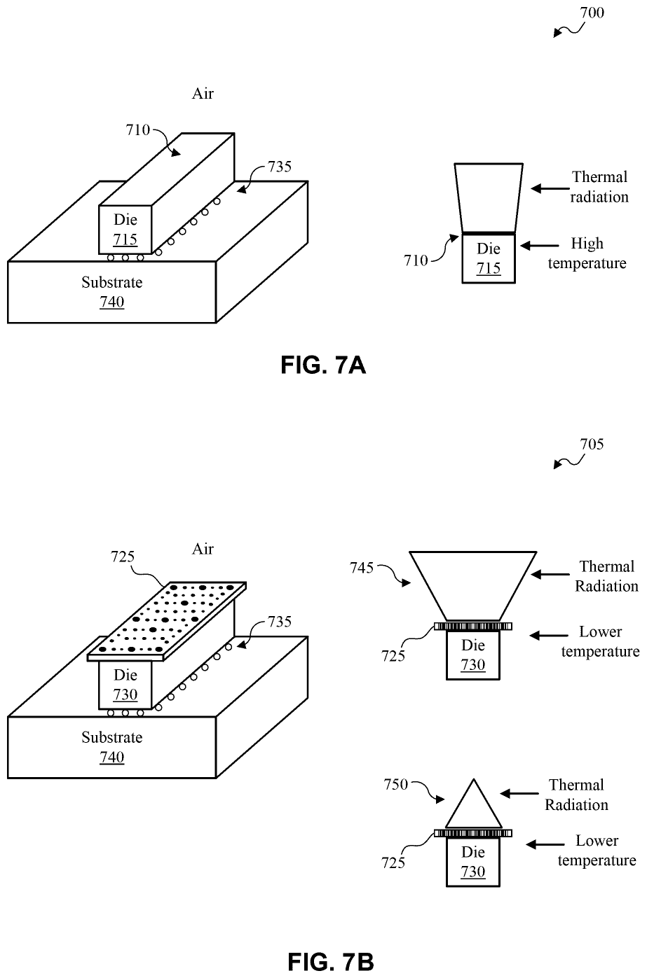

FIG. 7A illustrates an example system 700 in accordance with one or more implementations as described herein. System 700 depicts a three-dimensional view of system 700 adjacent to a corresponding side view of system 700.

As shown, system 700 includes die 715 with a flat silicon surface 710. Die 715 may be an example of image processor 115 of FIG. 1, electronics 245 of FIG. 2, electronics 355 of FIG. 3B, electronics 450 of FIG. 4B, electronics 520 of FIG. 5, some other processor (e.g., field programmable gate array (FPGA), application specific integrated circuit (ASIC), graphic processing unit (GPU), etc.), and/or some other heat-generating electronic component. System 700 depicts flat silicon surface 710 in relation to die 715. As shown, flat silicon surface 710 may be positioned on a surface of die 715. In some examples, a surface of flat silicon surface 710 may be exposed to air. As shown, die 715 generates heat during device/circuit operation. In the illustrated example, flat silicon surface 710 on top of die 715 does not include phase-modulating features of a phase modulating thin film (e.g., holes, etc.). As a result, flat silicon surface 710 has lower surface area, lower thermal emissivity, and lower directional control over emission of thermal radiation resulting in relatively low and/or slow heat dissipation of heat generated by die 715 into the air. In this case, die 715 suffers from relatively high temperatures, which makes a device of system 700 more prone to overheating. FIG. 7B illustrates an example system 705 in accordance with one or more implementations as described herein. System 705 illustrates an example configuration of a phase modulating thin film. In some examples, system 705 depicts a three-dimensional view of system 705 adjacent to a corresponding side view of system 705, which includes a portion of a long-wave infrared phase modulating thin film (e.g., similar to thermal imaging system 200 of FIG. 2).

As shown, system 705 includes metalens 725, die 730, ball grid array 735, and substrate 740. Metalens 725 may be an example of or similar to metalens 205 of FIG. 2, metalens 330 of FIG. 3B, metalens 425 of FIG. 4B, metalens 510 of FIG. 5, metalens 610 of FIG. 6A, and/or metalens 625 of FIG. 6B. Die 730 may be an example of image processor 115 of FIG. 1, electronics 245 of FIG. 2, electronics 355 of FIG. 3B, electronics 450 of FIG. 4B, electronics 520 of FIG. 5, die 715 of FIG. 7A, some other processor (e.g., field programmable gate array (FPGA), application specific integrated circuit (ASIC), graphic processing unit (GPU), etc.), and/or some other heat-generating electronic component. System 700 depicts metalens 725 (e.g., thermal phase modulating thin film metalens) in relation to die 730, where metalens 725 is configured for routing and/or dissipating heat (e.g., based on one or more phase modulating thin film features of metalens 725). In some implementations, metalens 725 may be exposed to air. In some examples, metalens 725 can be placed between die 730 and substrate 740 (e.g., on top of an interposer). Additionally, or alternatively, metalens 725 can be placed on top of die 730 and exposed to air to efficiently dissipate heat. Accordingly, the microscale thermal phase modulating thin film features of metalens 725 may be fabricated on a top surface of die 730 to provide higher surface area, higher thermal emissivity, direction control (lensing) of thermal radiation emission and, therefore, more efficient heat dissipation. As shown, metalens 725 may be configured to expand thermal radiation outward (e.g., directed thermal radiation 745). Alternatively, metalens 725 may be configured to steer thermal radiation in one or more directions (e.g., contracted or focused as with directed thermal radiation 750). Based on the thermal phase modulating features of metalens 725, metalens 725 provides efficient dispersion of heat generated by die 730, and reduction in temperature. As shown, based on metalens 725, heat generated by die 730 is dissipated more efficiently as compared to die 715, whereas die 715 experiences higher temperature while operating under similar conditions. Accordingly, metalens 725 improves thermal management (e.g., in micron scale) by dispersing LWIR wavelengths based on the phase modulating thin film features of metalens 725.

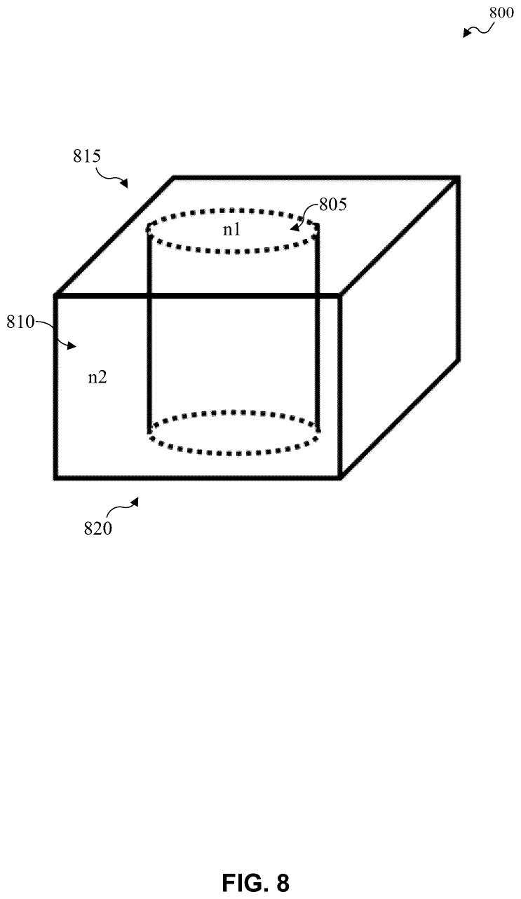

FIG. 8 illustrates an example metalens element 800 in accordance with one or more implementations as described herein. Metalens element 800 illustrates an example of an element of a phase modulating thin film for long-wave infrared thermal imaging. In some examples, metalens element 800 depicts a three-dimensional view of an element of a metalens of a thermal imaging system, such as thermal imaging system 100 of FIG. 1 and/or thermal imaging system 200 of FIG. 2.

As shown, metalens element 800 depicts a portion of a hole-based and/or pillar-based LWIR metalens. As shown, FIG. 8 depicts a hole 805 with a first refractive index (n1) based on a material filling hole 805 and a surrounding medium 810 with a second refractive index (n2) based on a material surrounding hole 805. In some examples, at least a portion of a metalens may be considered a hole-based portion of the metalens when n2 is greater than n1 (e.g., for a pattern of metalens elements similar to metalens element 800). Additionally, or alternatively, at least a portion of a metalens may be considered a pillar-based portion of the metalens when n1 is greater than n2 (e.g., based on a pattern of elements similar to metalens element 800). In some cases, transmission through a metalens may be increased by increasing the aspect ratio of hole 805 and/or by filling hole 805 with a low refractive index material. In some examples, an aspect ratio between a diameter of hole 805 and a depth of hole 805 may be between 1:6 and 1:3.

In one or more examples, surrounding medium 810 may be a material with a high index of refraction with respect to target wavelengths of the metalens, while hole 805 may be a material with a low index of refraction with respect to the target wavelengths of the metalens. Alternatively, surrounding medium 810 may be a material with a low index of refraction with respect to the target wavelengths of the metalens, while hole 805 may be a material with a high index of refraction with respect to the target wavelengths of the metalens. In some embodiments, hole 805 may be left open so that air forms the low-index material, such that the metalens elements are holes within surrounding medium 810. In further embodiments, liquid-crystal materials may be used for either surrounding medium 810 or hole 805 with the liquid crystal being switchable between a high index of refraction and a low index of refraction. Additionally, or alternatively, the liquid crystal may be switchable between polarization states. In further embodiments, the liquid-crystal materials may be used with a high-index material or a low-index material. As used herein, high index of refraction and low index of refraction are used in a relative term towards each other. For example, in some embodiments, a high index of refraction may be 1.5 or higher while a low index of refraction may be 1.5 or less. In some embodiments, a ratio between the high-index material and the low-index material may between 1.5 and 3. Such a difference in index of refraction may be used along with other variables to control the phase changes of electromagnetic radiation through such a metalens.

In an example implementation in which surrounding medium 810 is a material with a low index of refraction and hole 805 is a material with a high index of refraction, the combination may produce an effect similar to creating an array of pillars. As such, specifics for pattern of the array of metalens elements (e.g., nanostructure pattern), as well as the size of the pattern, the lattice spacing between individual metalens elements, the height of the individual metalens elements and the width of the individual metalens elements may be similar to a nanopillar array to produce the desired phase modulation on a target wavelength.

In an example implementation in which surrounding medium 810 is a material with a high index of refraction and hole 805 is a material with a low index of refraction, the combination may produce an effect similar to creating an array of holes within a thin layer. However, the use of a hole 805 allows for a controlled index of refraction.

Furthermore, while metalens element 800 is depicted as having a cylindrical shape, the shape of metalens elements may vary. For example, a metalens may include metalens elements of varying shapes that include prisms with polygonal cross-sections including rectangular prisms, cubes, etc., as well as shapes featuring various forms of conic section cross-sections, and other shapes such as arrows, stars, etc. Furthermore, a given metalens may include metalens elements of varying shapes with multiple widths and depths in a shared pattern.

The phase modulation of a pillar-based metalens based on metalens element 800 may depend on at least one of pillar height, width, and/or periodicity. For example, a metasurface based on metalens element 800 can be designed to provide a desired phase shift range. For example, a pillar height of 15 μm can provide a 2Pi radians) (360° phase shift for a pillar width range of 1.5 to 7.5 μm (periodicity: 8 μm). For a given pillar-based metalens based on metalens element 800, the numerical aperture (NA) may be 0.35, the focal spot size 10 μm, transmission (T) of 77.5% (77.5% of total energy passes through), and focusing efficiency of 26% (e.g. 26% energy loss).

In some examples, a hole-based phase modulating thin film based on metalens element 800 may be configured for a variety of applications (e.g., for focusing applications). Depending on the hole depth, width, and periodicity, a hole-based metasurface may be designed to provide any phase shift range from 0 to 2Pi radians (0-360°). In some examples, hole depth may be at or relatively near 12 μm (e.g., 5-20 μm in depth), which can provide a 2Pi phase shift for a hole width range of 1-3 μm (e.g., based on periodicity of 4 μm). For a given silicon hole-based metalens based on metalens element 800, NA may be 0.33, focal spot size 10 μm, and T 82% (e.g., at 10 μm).

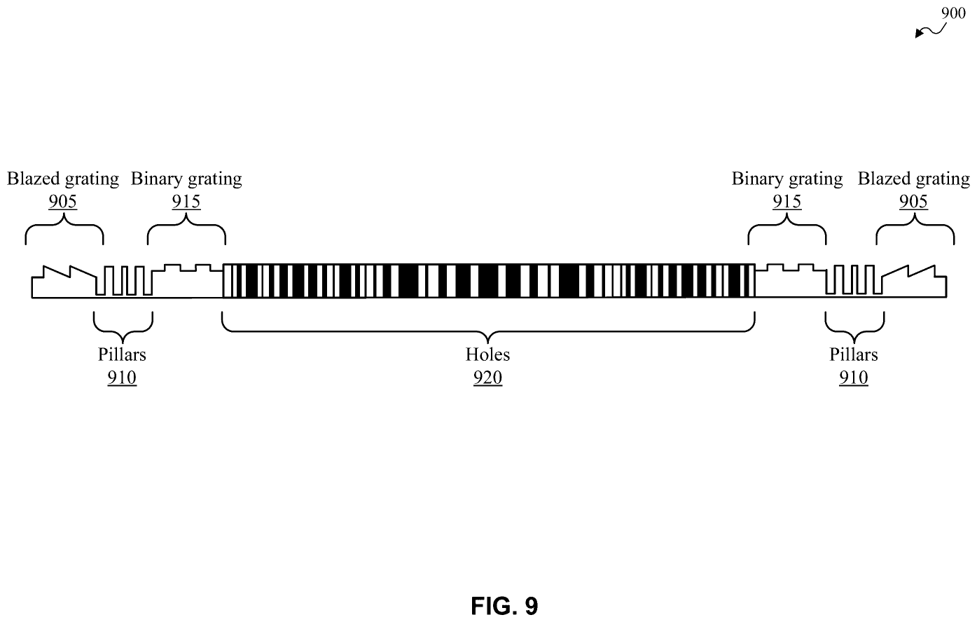

FIG. 9 illustrates an example metalens 900 in accordance with one or more implementations as described herein. In some examples, metalens 900 depicts a side view of a metalens that may be part of a thermal imaging system, such as thermal imaging system 100 of FIG. 1 and/or thermal imaging system 200 of FIG. 2. Metalens 900 may be an example of metalens 205 of FIG. 2, metalens 330 of FIG. 3B, metalens 425 of FIG. 4B, and/or metalens 510 of FIG. 5.

Metalens 900 may include at least one nanostructure. In some cases, a top surface of metalens 900 may include one or more nanostructures. Additionally, or alternatively, a bottom surface of metalens 900 may include one or more nanostructures. In some examples, at least one nanostructure of metalens 900 may be formed based on dry etching and/or wet etching.

In the illustrated example, metalens 900 may include nanostructures such as blazed gratings 905, pillars 910, binary gratings 915, and holes 920. In some examples, metalens 900 may include one or more patterns of diffraction grating (e.g., a pattern of blazed grating 905 and/or binary grating 915). In some cases, pillars 910 may include one or more patterns of pillars. In some implementations, holes 920 may include one or more patterns of holes (e.g., of a silicon hole-based metalens).

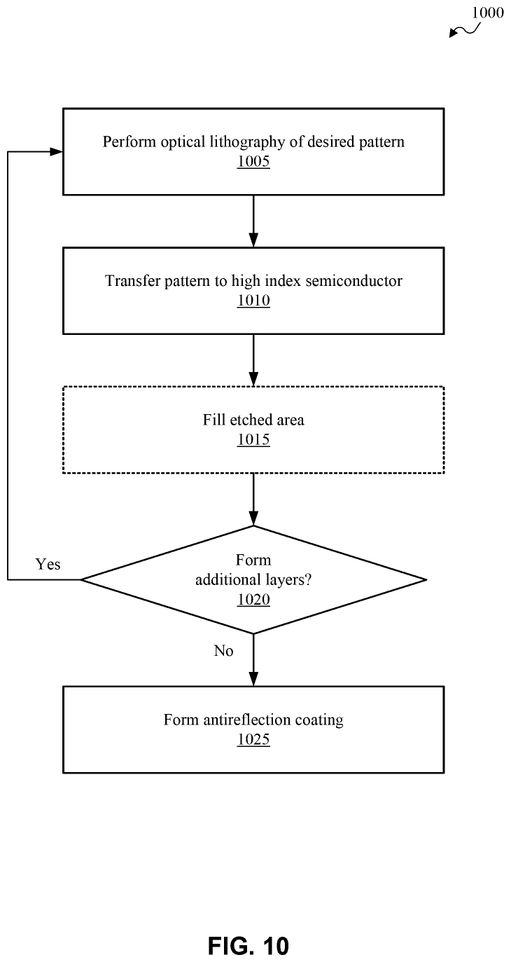

FIG. 10 depicts a flow diagram illustrating an example method 1000 associated with the disclosed systems, in accordance with example implementations described herein. The method 1000 is just one implementation and one or more operations of the method 1000 may be rearranged, reordered, omitted, and/or otherwise modified such that other implementations are possible and contemplated. FIG. 10 illustrates an example flow diagram of phase modulating thin film for long-wave infrared thermal imaging. Phase modulating thin film may include a structure or surface with one or more layers (e.g., of two or more different thin film materials). \

At 1005, method 1000 may include performing optical lithography of a desired pattern. For example, optical lithography may be performed with nanostructures in photoresist in relation to an individual pixel.

At 1010, method 1000 may include transferring the desired pattern to a high index semiconductor. The transfer of the pattern may be performed using dry etching or wet etching. Etching depth may vary from 1 to 50 times that of the pattern diameter.

At 1015, method 1000 may optionally include filling an etched area (e.g., gaps between pillars, holes, etc.). For example, the etched area or gaps between pillars may be filled with a low or high index material (e.g., index of refraction).

At 1020, method 1000 may include determining whether to form additional thin film layers. For example, method 1000 may include determining whether to repeat optical lithography at 1005, transferring of the desired pattern at 1010, and/or filling of an etched area at 1015. Thus, two or more thin film layers may be formed. For example, if it is determined to form additional thin film layers, method 1000 may return to 1005. When it is determined there are no additional thin film layers to form, method 1000 may proceed to 1025.

At 1025, method 1000 may include forming an antireflection coating. For example, method 1000 may include forming an antireflection coating on a phase modulating thin film layer (e.g., a top phase modulating thin film layer). In some cases, the antireflection coating may include multiple layers (e.g., two or more different materials).

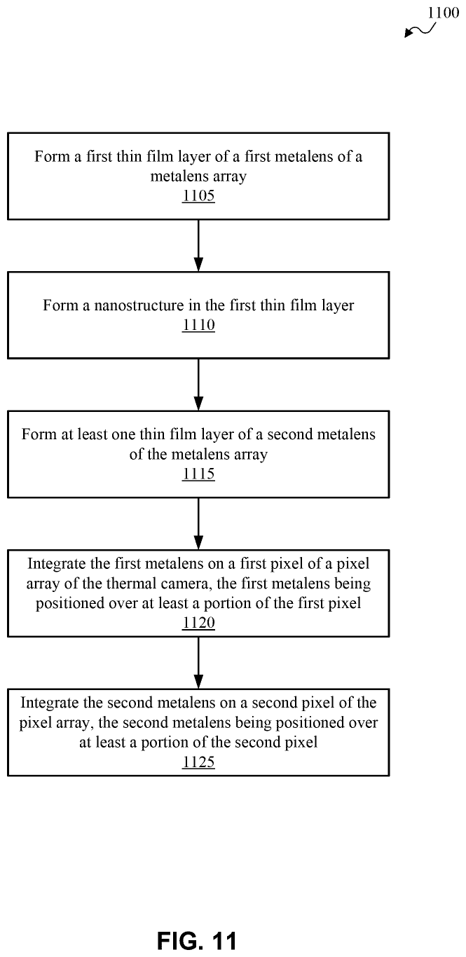

FIG. 11 depicts a flow diagram illustrating an example method 1100 associated with the disclosed systems, in accordance with example implementations described herein. The method 1100 is just one implementation and one or more operations of the method 1100 may be rearranged, reordered, omitted, and/or otherwise modified such that other implementations are possible and contemplated.

At 1105, method 1100 may include forming a first thin film layer of a first metalens of the metalens array. For example, a thermal camera may be configured with a metalens array that includes multiple metalenses configured to focus thermal energy onto respective thermal sensors of a thermal sensor array.

At 1110, method 1100 may include forming a nanostructure in the first thin film layer. In some examples, the nanostructure may include at least one of a hole through the first thin film layer, a pillar extending from a bottom surface of the first thin film layer, or diffraction grating on at least one of a top surface or the bottom surface of the first thin film layer.

At 1115, method 1100 may include forming at least one thin film layer of a second metalens of the metalens array. For example, the metalens array of the thermal camera may include a second metalens for focusing thermal energy.

At 1120, method 1100 may include integrating the first metalens on a first pixel of a pixel array of the thermal camera, the first metalens being positioned over at least a portion of the first pixel. For example, the first metalens may be configured to focus thermal energy on to the first pixel, where the first pixel is configured to detect thermal energy (e.g., first pixel of a thermal sensor array).

At 1125, method 1100 may include integrating the second metalens on a second pixel of the pixel array, the second metalens being positioned over at least a portion of the second pixel. For example, the second metalens may be configured to focus thermal energy on to the second pixel, where the second pixel is configured to detect thermal energy (e.g., second pixel of the thermal sensor array).

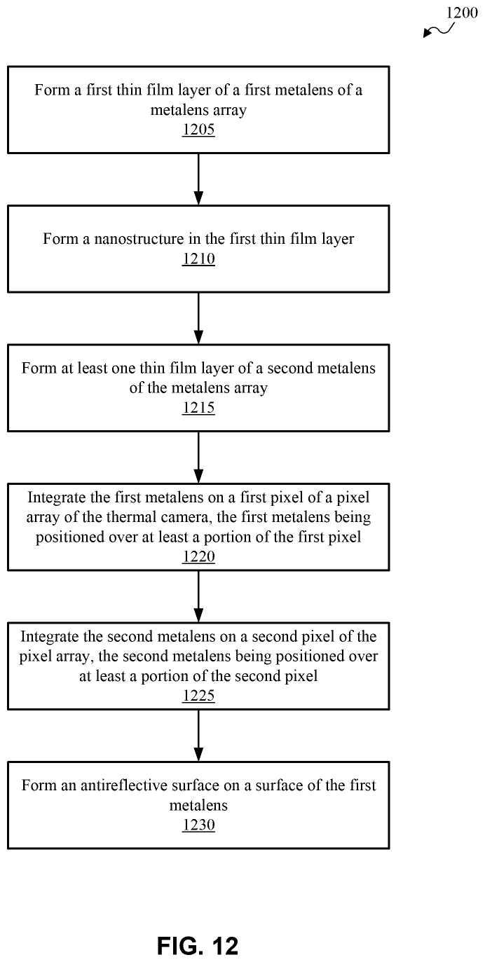

FIG. 12 depicts a flow diagram illustrating an example method 1200 associated with the disclosed systems, in accordance with example implementations described herein. The method 1200 is just one implementation and one or more operations of the method 1200 may be rearranged, reordered, omitted, and/or otherwise modified such that other implementations are possible and contemplated.

At 1205, method 1200 may include forming a first thin film layer of a first metalens of the metalens array. For example, a thermal camera may be configured with a metalens array that includes multiple metalenses configured to focus thermal energy onto respective thermal sensors of a thermal sensor array.

At 1210, method 1200 may include forming a nanostructure in the first thin film layer. In some examples, the nanostructure may include at least one of a hole through the first thin film layer, a pillar extending from a bottom surface of the first thin film layer, or diffraction grating on at least one of a top surface or the bottom surface of the first thin film layer.

At 1215, method 1200 may include forming at least one thin film layer of a second metalens of the metalens array. For example, the metalens array of the thermal camera may include a second metalens for focusing thermal energy.

At 1220, method 1200 may include integrating the first metalens on a first pixel of a pixel array of the thermal camera, the first metalens being positioned over at least a portion of the first pixel. For example, the first metalens may be configured to focus thermal energy on to the first pixel, where the first pixel is configured to detect thermal energy (e.g., first pixel of a thermal sensor array).

At 1225, method 1200 may include integrating the second metalens on a second pixel of the pixel array, the second metalens being positioned over at least a portion of the second pixel. For example, the second metalens may be configured to focus thermal energy on to the second pixel, where the second pixel is configured to detect thermal energy (e.g., second pixel of the thermal sensor array).

At 1230, method 1200 may include forming an antireflective surface on a surface of the first metalens. In some examples, the antireflective surface may include at least one of a dielectric material and/or an organic material (e.g., photoresist, an electron-beam resist, germanium, or zinc selenide).

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein (e.g., thermal image camera fabrication operations, metalens fabrication operations, thermal image processing operations, etc.).

Although an example thermal image processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device (e.g., thermal imaging display), for example a CRT (cathode ray tube) or LCD (liquid crystal display) monitor, for displaying information/data to the user and a keyboard and a pointing device, for example a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example as an information/data server, or that includes a middleware component, for example an application server, or that includes a front-end component, for example a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example an HTML page) to a client device (for example for purposes of displaying information/data to and receiving user input from a user interacting with the client device). Information/data generated at the client device (for example a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples described herein set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A method of forming a metalens array of a thermal camera, the method comprising:
forming a first thin film layer of a first metalens of the metalens array;
forming a nanostructure in the first thin film layer, the nanostructure including at least one of a hole through the first thin film layer, a pillar extending from a bottom surface of the first thin film layer, or diffraction grating on at least one of a top surface or the bottom surface of the first thin film layer;
forming at least one thin film layer of a second metalens of the metalens array;
integrating the first metalens on a first pixel of a pixel array of the thermal camera, the first metalens being positioned over at least a portion of the first pixel; and
integrating the second metalens on a second pixel of the pixel array, the second metalens being positioned over at least a portion of the second pixel.

2. The method of claim 1, further comprising forming a second thin film layer of the first metalens, wherein at least one of the first thin film layer or the second thin film layer is formed with at least one low refractive index material, at least one high refractive index material, or a combination of the at least one low refractive index material and the at least one high refractive index material.

3. The method of claim 1, further comprising forming an antireflective surface on a surface of the first metalens, the antireflective surface including at least one of photoresist, an electron-beam resist, a dielectric material, germanium, or zinc selenide.

4. The method of claim 1, wherein the nanostructure is configured to route thermal radiation incident upon the first metalens to a thermal sensor membrane of the first pixel, the first pixel being a first thermal sensor pixel, the pixel array comprising a thermal sensor array of the thermal camera.

5. The method of claim 1, wherein the nanostructure is configured to modulate a phase of thermal radiation incident on the first metalens.

6. The method of claim 1, wherein the nanostructure is configured to allow thermal radiation with wavelengths between 8 and 15 micrometers to pass through the first metalens.

7. The method of claim 1, wherein the first metalens includes at least one embedded liquid crystal layer.

8. The method of claim 1, wherein the nanostructure of the first metalens provides up to a 2Pi phase shift of thermal radiation incident upon the first metalens.

9. The method of claim 1, wherein, based on the nanostructure, a phase modulation of the first metalens varies from a phase modulation of the second metalens.

10. The method of claim 1, wherein:
the metalens array is configured as a global lens of the thermal camera, and
based at least on the nanostructure, a phase profile of each metalens of the metalens array is configured to vary spatially across the pixel array.

11. The method of claim 1, wherein a diameter of the hole or the pillar ranges between 100 micrometers and 1 nanometer.

12. A thermal camera, comprising:
a first thin film layer of a first metalens of a metalens array of the thermal camera;
a nanostructure formed in the first thin film layer, the nanostructure including at least one of a hole through the first thin film layer, a pillar extending from a bottom surface of the first thin film layer, or diffraction grating on at least one of a top surface or the bottom surface of the first thin film layer; and
at least one thin film layer of a second metalens of the metalens array, wherein:
the first metalens is integrated on a first pixel of a pixel array of the thermal camera, the first metalens being positioned over at least a portion of the first pixel; and
the second metalens is integrated on a second pixel of the pixel array, the second metalens being positioned over at least a portion of the second pixel.

13. The thermal camera of claim 12, wherein:
the first metalens further comprises a second thin film layer, and
at least one of the first thin film layer or the second thin film layer is formed with at least one low refractive index material, at least one high refractive index material, or a combination of the at least one low refractive index material and the at least one high refractive index material.

14. The thermal camera of claim 12, wherein the thermal camera further comprises an antireflective surface formed on a surface of the first metalens, the antireflective surface including at least one of a photoresist, an electron-beam resist, a dielectric material, germanium, or zinc selenide.

15. The thermal camera of claim 12, wherein the nanostructure is configured to route thermal radiation incident upon the first metalens to a thermal sensor membrane of the first pixel, the first pixel being a first thermal sensor pixel, the pixel array comprising a thermal sensor array of the thermal camera.

16. The thermal camera of claim 12, wherein the nanostructure is configured to modulate a phase of thermal radiation incident on the first metalens.

17. The thermal camera of claim 12, wherein the nanostructure is configured to allow thermal radiation with wavelengths between 8 and 15 micrometers to pass through the first metalens.

18. A thermal camera system comprising:
a metalens array configured to guide thermal radiation, the metalens array including:
a first thin film layer of a first metalens;
at least one thin film layer of a second metalens; and
a nanostructure formed in the first thin film layer, the nanostructure including at least one of a hole through the first thin film layer, a pillar extending from a bottom surface of the first thin film layer, or diffraction grating on at least one of a top surface or the bottom surface of the first thin film layer;
a thermal sensor array configured to detect the thermal radiation via the metalens array, wherein:
the first metalens is integrated on a first pixel of the thermal sensor array, the first metalens being positioned over at least a portion of the first pixel, and
the second metalens is integrated on a second pixel of the thermal sensor array, the second metalens being positioned over at least a portion of the second pixel;
an image processor to process signals of the thermal radiation generated by the thermal sensor array; and
a thermal display configured to indicate a relative temperature of an object based on an output of the image processor.

19. The thermal camera system of claim 18, wherein:
the first metalens further comprises a second thin film layer, and
at least one of the first thin film layer or the second thin film layer is formed with at least one low refractive index material, at least one high refractive index material, or a combination of the at least one low refractive index material and the at least one high refractive index material.

20. The thermal camera system of claim 18, wherein the thermal camera system further comprises an antireflective surface formed on a surface of the first metalens, the antireflective surface including at least one of a photoresist, an electron-beam resist, a dielectric material, germanium, or zinc selenide.
